(19) United States
(12) Patent Application Publication
(10) Pub. No.: US 2025/0070645 A1
(43) Pub. Date: Feb. 27, 2025

(54) GATE DRIVE CIRCUIT, POWER GOOD CIRCUIT, OVERCURRENT DETECTION CIRCUIT, OSCILLATION PREVENTION CIRCUIT, SWITCHING CONTROL CIRCUIT AND SWITCHING POWER SUPPLY DEVICE

(71) Applicant: ROHM CO., LTD., Kyoto (JP)

(72) Inventors: Haruo YAMAKOSHI, Kyoto (JP); Naoyuki SAKAWA, Kyoto (JP); Tomoaki OSHIMI, Kyoto (JP)

(21) Appl. No.: 18/940,202

(22) Filed: Nov. 7, 2024

Related U.S. Application Data
(63) Continuation of application No. PCT/JP2023/017044, filed on May 1, 2023.

(30) Foreign Application Priority Data
May 9, 2022 (JP) 2022-076912
May 25, 2022 (JP) 2022-085294
May 25, 2022 (JP) 2022-085302
May 26, 2022 (JP) 2022-086054

(51) Int. Cl. H02M 1/088; H02M 1/32; H02M 3/158

(52) U.S. Cl. CPC H02M 1/088; H02M 1/32; H02M 3/158

(57) ABSTRACT

A high-side pre-driver includes a first high-side transistor and a second high-side transistor, a low-side pre-driver includes a third high-side transistor and a fourth high-side transistor and a delay is provided in at least one of a time period between a first gate signal configured to turn on the first high-side transistor and a second gate signal configured to turn on the second high-side transistor and a time period between a third gate signal configured to turn on the third high-side transistor and a fourth gate signal configured to turn on the fourth high-side transistor.

### CROSS-REFERENCE TO RELATED APPLICATIONS

This nonprovisional application is a continuation application of International Patent Application No. PCT/JP2023/017044 filed on May 1, 2023, which claims priority to Japanese Patent Application No. 2022-076912 filed on May 9, 2022, Japanese Patent Application No. 2022-085294 filed on May 25, 2022, Japanese Patent Application No. 2022-085302 filed on May 25, 2022, Japanese Patent Application No. 2022-086054 filed on May 26, 2022, the entire contents of which are hereby incorporated by reference.

### TECHNICAL FIELD

The invention disclosed in the present specification relates to a gate drive circuit. The invention disclosed in the present specification also relates to a power good circuit. The invention disclosed in the present specification also relates to an overcurrent detection circuit, an oscillation prevention circuit and a switching control circuit and a switching power supply device which include the overcurrent detection circuit or the oscillation prevention circuit.

### BACKGROUND ART

Conventionally, a gate drive circuit is known which drives the gates of a high-side transistor and a low-side transistor connected in series (for example, Patent Document 1). For example, the high-side transistor and the low-side transistor each are formed with an N-channel MOSFET (metal-oxide-semiconductor field effect transistor).

When one of the high-side transistor and the low-side transistor is turned on (switched from an off-state to an on-state), and the other is turned off (switched from the on-state to the off-state), a voltage change occurs at a node where the high-side transistor and the low-side transistor are connected. Hence, the Vds (drain-source voltage) of the transistor which is turned off is changed. When the slew rate (slope of a change over time) of the voltage change at the node is high, the Vgs (gate-source voltage) of the transistor which is turned off is raised, with the result that the transistor may be self-turned on.

Conventionally, a power supply IC (Integrated Circuit) which includes a power good circuit is known. The power good circuit is a circuit which has the function of outputting a flag when the output voltage of a power supply circuit reaches a voltage value which is set (for example, Patent Document 2). In this way, for example, it is possible to notify an IC (such as a CPU (Central Processing Unit)) outside the power supply IC that the output voltage has normally rosed.

Conventionally, in a switching power supply device which complementarily switches an upper transistor and a lower transistor, a lower overcurrent detection circuit which detects an overcurrent flowing through the lower transistor may be provided (see, for example, Patent Document 3).

Conventionally, a switching power supply device which includes an error amplifier is developed (see, for example, Patent Document 4). In the switching power supply device including the error amplifier, the error amplifier generates an error signal corresponding to a difference between a feedback voltage and a reference voltage, and thus a switching control circuit controls a switching element based on the error signal.

In a switching power supply device proposed in Patent Document 4, a capacitor provided between the output end of an error amplifier and the ground end prevents the oscillation of the error amplifier.

### RELATED ART DOCUMENT

### Patent Document

Patent Document 1: Japanese Unexamined Patent Application Publication No. 2022-15863
Patent Document 2: Japanese Unexamined Patent Application Publication No. 2021-93841
Patent Document 3: Japanese Unexamined Patent Application Publication No. 2014-150675
Patent Document 4: Japanese Unexamined Patent Application Publication No. 2014-117042

### BRIEF DESCRIPTION OF DRAWINGS

FIG. 1 is a diagram showing the configuration of a semiconductor device in a first embodiment of the present disclosure;

FIG. 2 is a diagram showing a specific configuration example of a gate drive circuit;

FIG. 3 is a diagram showing a configuration example of a first high-side drive unit;

FIG. 4 is a timing chart showing an operation when a high-side transistor is turned on and a low-side transistor is turned off;

FIG. 5 is a timing chart showing an operation when the high-side transistor is turned off and the low-side transistor is turned on in the embodiment of the present disclosure;

FIG. 6 is a diagram showing a configuration example of the first low-side drive unit;

FIG. 7 is a diagram showing the configuration of a gate drive circuit according to a second embodiment of the present disclosure;

FIG. 8 is a diagram showing a configuration example of a high-side gate voltage monitoring unit;

FIG. 9 is a diagram showing a configuration example of a first low-side drive unit;

FIG. 10 is a timing chart showing an operation when a high-side transistor is turned off and a low-side transistor is turned on in the second embodiment of the present disclosure;

FIG. 11 is a timing chart showing an operation when the high-side transistor is turned off and the low-side transistor is turned on in the embodiment of the present disclosure;

FIG. 12 is a diagram showing the configuration of a semiconductor device in an illustrative embodiment of the present disclosure;

FIG. 13 is a diagram showing a part of an internal configuration of the semiconductor device;

FIG. 14 is a diagram showing a configuration example of a pre-regulator;

FIG. 15 is a diagram showing the configuration of a power good circuit in a comparative example;

FIG. 16 is a timing chart showing an operation of the power good circuit in the comparative example when a power supply IC is started up;

FIG. 17 is a diagram showing the configuration of a power good circuit according to the first embodiment of the present disclosure;

FIG. 18 is a timing chart showing operations of the power good circuit according to the first embodiment when the power supply IC is started up and when the power supply IC is shut down;

FIG. 19 is a diagram showing the configuration of a power good circuit according to the second embodiment of the present disclosure;

FIG. 20 is a timing chart showing operations of the power good circuit according to the second embodiment when the power supply IC is started up and when the power supply IC is shut down;

FIG. 21 is a diagram showing the configuration of a power good circuit according to a third embodiment of the present disclosure;

FIG. 22 is a timing chart showing operations of the power good circuit according to the third embodiment when the power supply IC is started up and when the power supply IC is shut down;

FIG. 23 is a diagram showing an overall configuration of the switching power supply device;

FIG. 24 is a diagram showing an internal configuration of the semiconductor device;

FIG. 25 is a diagram showing a comparative example of a lower overcurrent detection circuit;

FIG. 26 is a timing chart showing ideal waveforms of voltages and currents at parts of a switching power supply device;

FIG. 27 is a timing chart showing actual waveforms of voltages and currents at the parts of the switching power supply device;

FIG. 28 is a diagram showing a first embodiment of the lower overcurrent detection circuit;

FIG. 29 is a diagram showing a first configuration example of a current generation circuit;

FIG. 30 is a timing chart showing actual waveforms of voltages and currents at parts of a switching power supply device which includes the lower overcurrent detection circuit in the first embodiment;

FIG. 31 is a diagram showing a second configuration example of the current generation circuit;

FIG. 32 is a diagram showing a third configuration example of the current generation circuit;

FIG. 33 is a diagram showing a fourth configuration example of the current generation circuit;

FIG. 34 is a diagram showing a fifth configuration example of the current generation circuit;

FIG. 35A is a diagram showing a variation of a first circuit;

FIG. 35B is a diagram showing another variation of the first circuit;

FIG. 36A is a diagram showing a variation of a second circuit;

FIG. 36B is a diagram showing another variation of the second circuit;

FIG. 36C is a diagram showing yet another variation of the second circuit;

FIG. 37 is a timing chart showing actual waveforms of voltages and currents at parts of a switching power supply device which includes the current generation circuit in the fifth configuration example;

FIG. 38 is a diagram showing a second embodiment of the lower overcurrent detection circuit;

FIG. 39 is a timing chart showing actual waveforms of voltages and currents at parts of a switching power supply device which includes the lower overcurrent detection circuit in the second embodiment;

FIG. 40 is a diagram showing a third embodiment of the lower overcurrent detection circuit;

FIG. 41 is a diagram showing an overall configuration of the switching power supply device;

FIG. 42 is a diagram showing an internal configuration of the semiconductor device;

FIG. 43 is a diagram showing a configuration example of the error amplifier, an upper clamp circuit and a lower clamp circuit;

FIG. 44 is a diagram showing the frequency characteristics of the lower clamp circuit;

FIG. 45 is a diagram showing the frequency characteristics of the upper clamp circuit;

FIG. 46 is a diagram showing the frequency characteristics of the upper clamp circuit, a capacitor and a resistor; and

FIG. 47 is a diagram showing a configuration example of a differential amplifier.

### DESCRIPTION OF EMBODIMENTS

In the present specification, a MOS field effect transistor (MOSFET [Metal-Oxide-Semiconductor Field Effect Transistor]) refers to a field effect transistor in which a gate structure includes at least three layers of a “layer formed of a conductor or a semiconductor such as polysilicon having a low resistance value”, an “insulating layer” and a “p-type, n-type or intrinsic semiconductor layer”. In other words, the gate structure of the MOS field effect transistor is not limited to a three-layer structure of a metal, an oxide and a semiconductor.

In the present specification, a reference voltage means a constant voltage in an ideal state, and is actually a voltage which can slightly vary due to a temperature change or the like.

In each of first to fourth disclosed techniques described below, it is assumed that reference symbols which represent constituent elements and signals are not related to each other. In other words, even when the same symbols are provided, they may represent different constituent elements and signals.

### First Disclosed Technique

### 1. First Embodiment

### <Configuration of Semiconductor Device>

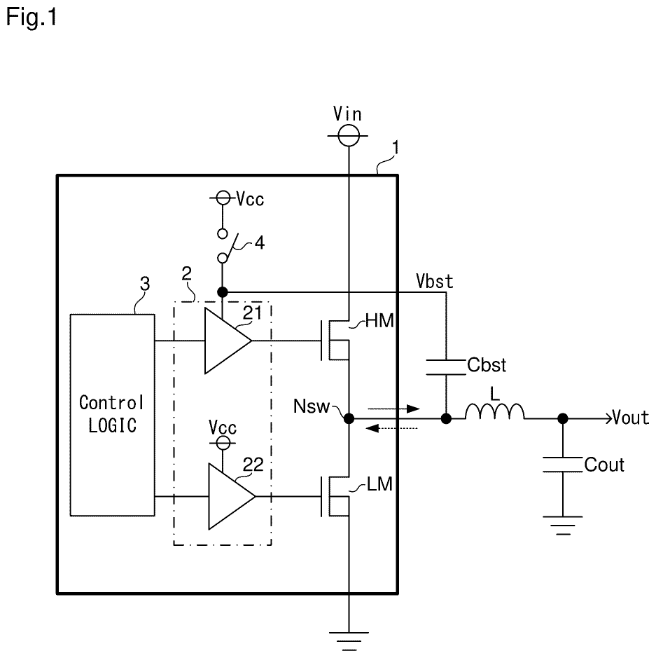

FIG. 1 is a diagram showing the configuration of a semiconductor device 1 in a first embodiment of the present disclosure. The semiconductor device 1 is a device obtained by packaging a power supply IC which has a DC/DC converter function. As shown in FIG. 1, the semiconductor device 1 includes a high-side transistor HM, a low-side transistor LM, a gate drive circuit 2, a control logic unit 3 and a switch 4 by integrating them.

Outside the semiconductor device 1, an inductor L, an output capacitor Cout and a boot capacitor Cbst are provided. A step-down DC/DC converter is formed with these external elements and the semiconductor device 1.

Each of the high-side transistor HM and the low-side transistor LM is formed with an NMOS transistor (N-channel MOSFET). The drain of the high-side transistor HM is connected to the application end of an input voltage Vin. The source of the high-side transistor HM is connected to the drain of the low-side transistor LM. The source of the low-side transistor LM is connected to the application end of a ground potential. In other words, the high-side transistor HM and the low-side transistor LM are connected in series between the input voltage Vin and the ground potential. A so-called half bridge is formed with the high-side transistor HM and the low-side transistor LM.

A node Nsw where the source of the high-side transistor HM and the drain of the low-side transistor LM are connected is connected to one end of the inductor L. The other end of the inductor L is connected to one end of the output capacitor Cout. The other end of the output capacitor Cout is connected to the application end of the ground potential. An output voltage Vout is generated at the one end of the output capacitor Cout.

The gate drive circuit 2 is a circuit which drives the gates of the high-side transistor HM and the low-side transistor LM, and includes a high-side pre-driver 21 and a low-side pre-driver 22.

The high-side pre-driver 21 drives the gate of the high-side transistor HM based on a control signal input from the control logic unit 3. The low-side pre-driver 22 drives the gate of the low-side transistor LM based on a control signal input from the control logic unit 3. The pre-drivers 21 and 22 complementarily switch and drive the transistors HM and LM, and thus the input voltage Vin is converted into the output voltage Vout.

The boot capacitor Cost and the switch 4 are used to form a bootstrap. One end of the boot capacitor Cost is connected to the one end of the inductor L. The other end of the boot capacitor Cbst is connected to the high-side pre-driver 21. The other end of the boot capacitor Cost is connected via the switch 4 to the application end of a power supply voltage VCC. The power supply voltage VCC is, for example, an internal voltage which is generated by a LDO (Low Dropout) based on the input voltage Vin.

When the high-side transistor HM is in an off-state, and the low-side transistor LM is in an on-state, the switch 4 is brought into an on-state, and thus the boot capacitor Cbst is charged. When the high-side transistor HM is in the on-state, and the low-side transistor LM is in the off-state, the switch 4 is brought into the off-state, and thus a boot voltage Vbst which is generated in the boot capacitor Cost is supplied to the high-side pre-driver 21. The boot voltage Vbst is higher than the input voltage Vin, and thus the high-side transistor HM formed with the NMOS transistor can be brought into the on-state.

### <Configuration of Gate Drive Circuit>

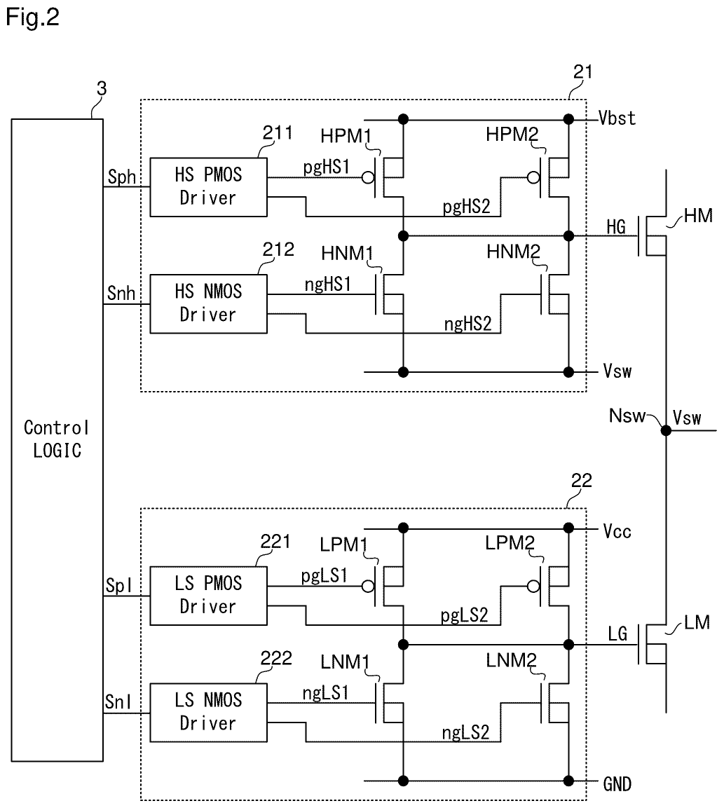

FIG. 2 is a diagram showing a specific configuration example of the gate drive circuit 2. The high-side pre-driver 21 includes a first high-side PMOS transistor (P-channel MOSFET) HPM1, a second high-side PMOS transistor HPM2, a first high-side NMOS transistor HNM1 and a second high-side NMOS transistor HNM2. The high-side pre-driver 21 further includes a first high-side drive unit (high-side PMOS drive unit) 211 which drives the high-side PMOS transistors HPM1 and HPM2 and a second high-side drive unit (high-side NMOS drive unit) 212 which drives the high-side NMOS transistors HNM1 and HNM2.

The sources of the high-side PMOS transistors HPM1 and HPM2 are connected to the application end of the boot voltage Vbst. The drains of the high-side PMOS transistors HPM1 and HPM2 are connected to the drains of the high-side NMOS transistors HNM1 and HNM2. The sources of the high-side NMOS transistors HNM1 and HNM2 are connected to the application end of the switch voltage Vsw generated in the node Nsw. A node where the drains of the high-side PMOS transistors HPM1 and HPM2 and the drains of the high-side NMOS transistors HNM1 and HNM2 are connected is connected to the gate of the high-side transistor HM.

The first high-side drive unit 211 respectively applies gate signals pgHS1 and pgHS2 to the gates of the high-side PMOS transistors HPM1 and HPM2 to drive the gates of the high-side PMOS transistors HPM1 and HPM2. The second high-side drive unit 212 respectively applies gate signals ngHS1 and ngHS2 to the gates of the high-side NMOS transistors HNM1 and HNM2 to drive the gates of the high-side NMOS transistors HNM1 and HNM2.

The first high-side drive unit 211 outputs the gate signals pgHS1 and pgHS2 at a logic level corresponding to the logic level of a high-side control signal Sph input from the control logic unit 3. The second high-side drive unit 212 outputs the gate signals ngHS1 and ngHS2 at a logic level corresponding to the logic level of a high-side control signal Snh input from the control logic unit 3.

The low-side pre-driver 22 includes a first low-side PMOS transistor LPM1, a second low-side PMOS transistor LPM2, a first low-side NMOS transistor LNM1 and a second low-side NMOS transistor LNM2. The low-side pre-driver 22 further includes: a first low-side drive unit (low-side PMOS drive unit) 221 which drives the low-side PMOS transistors LPM1 and LPM2; and a second low-side drive unit (low-side NMOS drive unit) 222 which drives the low-side NMOS transistors LNM1 and LNM2.

The sources of the low-side PMOS transistors LPM1 and LPM2 are connected to the application end of the power supply voltage VCC. The drains of the low-side PMOS transistors LPM1 and LPM2 are connected to the drains of the low-side NMOS transistors LNM1 and LNM2. The sources of the low-side NMOS transistor LNM1 and LNM2 are connected to the application end of the ground potential. A node where the drains of the low-side PMOS transistors LPM1 and LPM2 and the drains of the low-side NMOS transistors LNM1 and LNM2 are connected is connected to the gate of the low-side transistor LM.

The first low-side drive unit 221 respectively applies gate signals pgLS1 and pgLS2 to the gates of the low-side PMOS transistors LPM1 and LPM2 to drive the gates of the low-side PMOS transistors LPM1 and LPM2. The second low-side drive unit 222 respectively applies gate signals ngLS1 and ngLS2 to the gates of the low-side NMOS transistors LNM1 and LNM2 to drive the gates of the low-side NMOS transistors LNM1 and LNM2.

The first low-side drive unit 221 outputs the gate signals pgLS1 and pgLS2 at a logic level corresponding to the logic level of a low-side control signal Spl input from the control logic unit 3. The second low-side drive unit 222 outputs the gate signals ngLS1 and ngLS2 at a logic level corresponding to the logic level of a low-side control signal Snl input from the control logic unit 3.

### <Configuration of High-Side Drive Unit>

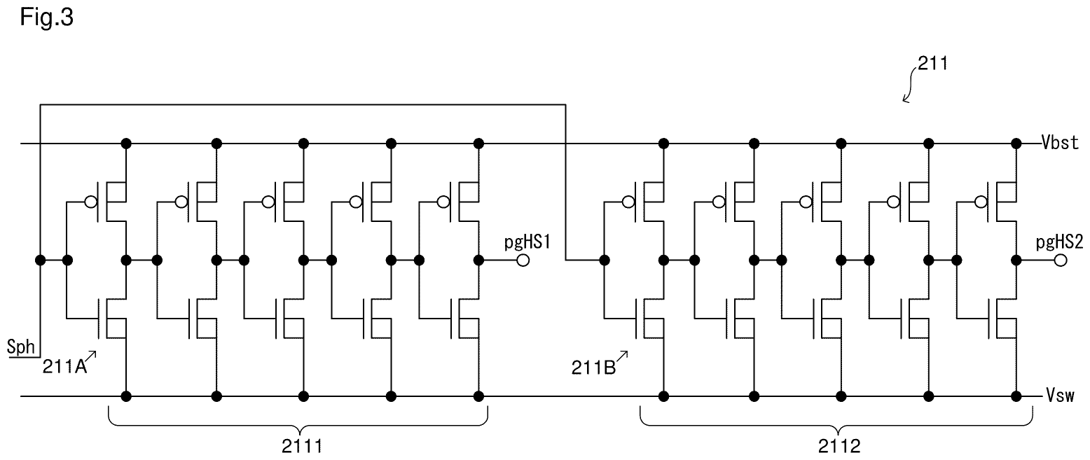

Here, the configuration of the high-side drive units 211 and 212 will be described. FIG. 3 is a diagram showing a configuration example of the first high-side drive unit 211. The first high-side drive unit 211 includes: a first high-side gate signal generation unit 2111 which generates the gate signal pgHS1 based on the high-side control signal Sph; and a second high-side gate signal generation unit 2112 which generates the gate signal pgHS2 based on the high-side control signal Sph.

The first high-side gate signal generation unit 2111 is formed with inverters 211A in five stages. The inverters 211A are formed with PMOS transistors and NMOS transistors which are connected in series between the boot voltage Vbst and the switch voltage Vsw. The high-side control signal Sph is input to the inverter 211A in the first stage, and the gate signal pgHS1 is output from the inverter 211A in the final stage.

The second high-side gate signal generation unit 2112 is formed with inverters 211B in five stages. The inverters 211B are formed with PMOS transistors and NMOS transistors which are connected in series between the boot voltage Vbst and the switch voltage Vsw. The high-side control signal Sph is input to the inverter 211B in the first stage, and the gate signal pgHS2 is output from the inverter 211B in the final stage.

The number of stages of each of the inverters 211A and the inverters 211B is not limited to five.

The configuration of the second high-side drive unit 212 is obtained by replacing, in the configuration shown in FIG. 3, the high-side control signal Sph with the high-side control signal Snh and the gate signals pgHS1 and pgHS2 with the gate signals ngHS1 and ngHS2.

<Operation when High-Side Transistor is Turned On>

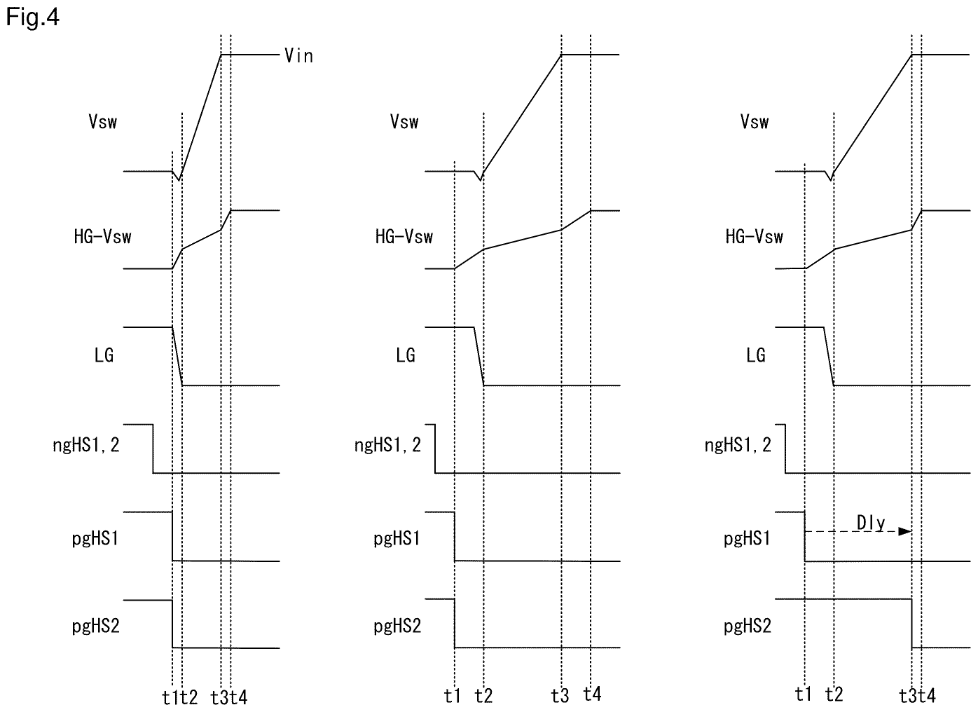

FIG. 4 is a timing chart showing an operation when the high-side transistor HM is turned on and the low-side transistor LM is turned off. FIG. 4 shows a case where a normal operation is performed. The normal operation refers to an operation when a current flows from the node Nsw to the side of the inductor L (solid arrow in FIG. 1). FIG. 4 shows three patterns which will be described later.

FIG. 4 shows, sequentially from the uppermost stage, examples of waveforms of the switch voltage Vsw, a high-side gate voltage HG, a low-side gate voltage LG, the gate signals ngHS1 and ngHS2 and the gate signals pgHS1 and pgHS2. The high-side gate voltage HG (FIG. 2) is a voltage which is applied to the gate of the high-side transistor HM with reference to the switch voltage Vsw, that is, the Vgs of the high-side transistor HM. The low-side gate voltage LG (FIG. 2) is a voltage which is applied to the gate of the low-side transistor LM with reference to the ground potential, that is, the Vgs of the low-side transistor LM.

The left side of FIG. 4 shows an operation when no delay is provided in the gate signals pgHS1 and pgHS2 as a comparison with the embodiment of the present disclosure. Initially, the high-side transistor HM is in the off-state, and the low-side transistor LM is in the on-state. Here, the discharge of the gate of the low-side transistor LM is started by the low-side pre-driver 22 (timing t1). Here, the low-side NMOS transistors LNM1 and LNM2 are turned on in a state where the low-side PMOS transistors LPM1 and LPM2 are in an off-state, and thus the low-side gate voltage LG starts to decrease.

Here, a voltage drop in the low-side transistor LM is increased by a current flowing through the low-side transistor LM, and thus the switch voltage Vsw is lowered. The low-side gate voltage LG is lowered to the ground potential (timing t2).

On the other hand, in the high-side pre-driver 21, after the gate signals ngHS1 and ngHS2 are switched from high to low, and thus the high-side NMOS transistors HNM1 and HNM2 are turned off, the gate signals pgHS1 and pgHS2 are switched from high to low, with the result that the high-side PMOS transistors HPM1 and HPM2 are turned on. Hence, a dead time (simultaneous off period) is provided.

The levels of the gate signals pgHS1 and pgHS2 are switched at the timing t1, and thus the high-side gate voltage HG starts to rise. As the high-side gate voltage HG rises from the timing t2, the switch voltage Vsw rises. As the high-side gate voltage HG rises, the on-resistance of the high-side transistor HM decreases, and thus a voltage drop in the high-side transistor HM decreases, with the result that the switch voltage Vsw rises.

Then, the switch voltage Vsw reaches the input voltage Vin (timing t3). The high-side gate voltage HG continues to rise after the timing t3 to reach the boot voltage Vbst at a timing t4.

As described above, in the operation shown in the left side of FIG. 4, no delay is provided in the gate signals pgHS1 and pgHS2, and simultaneously, the levels are switched low. When the sizes of the high-side PMOS transistors HPM1 and HPM2 are designed so as to increase the driving capability of the high-side transistor HM, the slope of a rise in the high-side gate voltage HG is increased during a period (timings t2 to t3) in which the switch voltage Vsw rises, with the result that the slew rate of the switch voltage Vsw is increased. In this way, in the operation shown in the left side of FIG. 4, it is likely that the Vgs of the low-side transistor LM is raised by a change in the Vds of the low-side transistor LM, and thus the low-side transistor LM is self-turned on.

Hence, in an operation shown in the center of FIG. 4, the driving capability of the high-side transistor HM caused by the high-side PMOS transistors HPM1 and HPM2 is lowered. For the control of the gate signals pgHS1 and pgHS2, as in the left side of FIG. 4, no delay is provided.

In this case, since the slew rate of the switch voltage Vsw is decreased, the self-turning on of the low-side transistor LM is suppressed (t2 to t3 in the center of FIG. 4). However, after the timing t3, the slope of a rise in the high-side gate voltage HG is decreased, and thus a time until the high-side gate voltage HG reaches the boot voltage Vbst is increased (t3 to t4). In this way, a loss in the on-resistance of the high-side transistor HM is increased, and thus the efficiency is disadvantageously lowered.

Hence, in the embodiment of the present disclosure, an operation as shown in the right side of FIG. 4 is adopted. Here, a delay Dly is provided in the gate signal pgHS2 with respect to the gate signal pgHS1. The delay time of the delay Dly is set such that the gate signal pgHS2 is switched low with the timing t3 at which the switch voltage Vsw reaches the input voltage Vin.

In this way, first, at the timing t1, the gate signal pgHS1 is switched low, and thus the high-side PMOS transistor HPM1 is turned on, and thereafter at the timing t3, the gate signal pgHS2 is switched low, and thus the high-side PMOS transistor HPM2 is turned on. Hence, during the period (t2 to t3) in which the switch voltage Vsw rises, only the high-side PMOS transistor HPM1 of the high-side PMOS transistors HPM1 and HPM2 is in an on-state, thus the driving capability is suppressed, the slope of the high-side gate voltage HG is decreased and thus the slew rate of the switch voltage Vsw is decreased. Furthermore, when the switch voltage Vsw reaches the input voltage Vin, both the high-side PMOS transistors HPM1 and HPM2 are brought into the on-state, thus the driving capability is increased and thus the slope of the high-side gate voltage HG is increased. Therefore, a time (t3 to t4) until the high-side gate voltage HG reaches the boot voltage Vbst is decreased. In other words, in the present embodiment, a decrease in the efficiency can be suppressed while the self-turning on of the low-side transistor LM is being suppressed.

Here, in order to switch the gate signals pgHS1 and pgHS2 low, in the first high-side drive unit 211 of the configuration shown in FIG. 3, the high-side control signal Sph is switched high. The gate signals pgHS1 and pgHS2 are switched with a delay from the switching of the high-side control signal Sph high caused by the gate signal generation units 2111 and 2112. Such a delay occurs due to the on-resistance of the transistors in the inverters 211A and 211B and capacitance caused by wiring, the gates of the transistors and the like.

In order to provide a delay in the gate signals pgHS1 and pgHS2, in the high-side gate signal generation units 2111 and 2112, the size of the NMOS transistor in the inverter 211B in the first stage is decreased beyond the size of the NMOS transistor in the inverter 211A in the first stage, and thus the on-resistance is adjusted. In the inverters 211A and 211B on the side of the subsequent stages, in order to secure the driving capability, it is necessary to increase the size of the transistors, and thus it is difficult to adjust the on-resistance, with the result that the size of the inverter in the first stage is adjusted. For example, in addition to the first stage, the size of the transistor in the inverter in the second stage may be adjusted.

<Operation when Low-Side Transistor is Turned On>

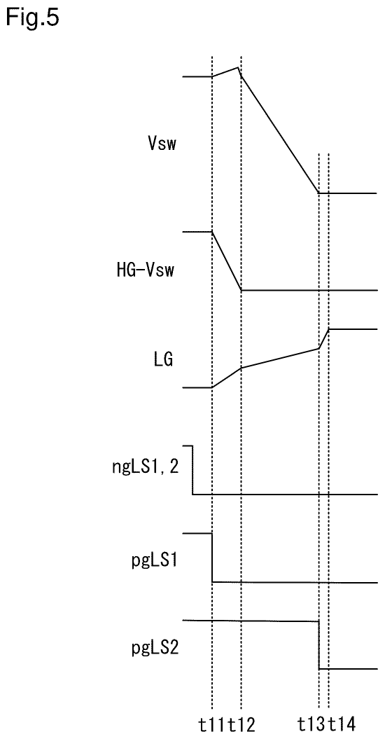

FIG. 5 is a timing chart showing an operation when the high-side transistor HM is turned off and the low-side transistor LM is turned on in the embodiment of the present disclosure. FIG. 5 shows a case where a reverse flow operation is performed. The reverse flow operation refers to an operation when a current flows from the inductor L to the side of the node Nsw (dotted arrow in FIG. 1).

FIG. 5 shows, sequentially from the uppermost stage, examples of waveforms of the switch voltage Vsw, the high-side gate voltage HG, the low-side gate voltage LG, the gate signals ngLS1 and ngLS2 and the gate signals pgLS1 and pgLS2. As shown in FIG. 5, a delay is provided in the gate signals pgLS1 and pgLS2.

Initially, the high-side transistor HM is in the on-state, and the low-side transistor LM is in the off-state. Here, the discharge of the gate of the high-side transistor HM is started by the high-side pre-driver 21 (timing t11). Here, the high-side NMOS transistors HNM1 and HNM2 are turned on in a state where the high-side PMOS transistors HPM1 and HPM2 are in the off-state, and thus the high-side gate voltage HG starts to decrease.

Here, a voltage drop in the high-side transistor HM is increased by a current flowing through the high-side transistor HM, and thus the switch voltage Vsw is increased. The high-side gate voltage HG is lowered to the switch voltage Vsw (timing t12).

On the other hand, in the low-side pre-driver 22, after the gate signals ngLS1 and ngLS2 are switched from high to low, and thus the low-side NMOS transistors LNM1 and LNM2 are turned off, the gate signal pgLS1 is switched from high to low, with the result that the low-side PMOS transistor LPM1 is turned on. Hence, a dead time is provided.

The level of the gate signal pgLS1 is switched at the timing t11, and thus the low-side gate voltage LG starts to rise. As the low-side gate voltage LG rises from the timing t12, the switch voltage Vsw decreases. As the low-side gate voltage LG rises, the on-resistance of the low-side transistor LM decreases, and thus a voltage drop in the low-side transistor LM decreases, with the result that the switch voltage Vsw decreases.

Then, the switch voltage Vsw reaches the ground potential (timing t13). Here, the gate signal pgLS2 is switched low. In this way, the low-side PMOS transistor LPM2 is turned on. The low-side gate voltage LG continues to rise after the timing t13 to reach the power supply voltage VCC at a timing t14.

In this way, first, at the timing t11, the gate signal pgLS1 is switched low, and thus the low-side PMOS transistor LPM1 is turned on, and thereafter at the timing t13, the gate signal pgLS2 is switched low, and thus the low-side PMOS transistor LPM2 is turned on. Hence, during the period (t12 to t13) in which the switch voltage Vsw decreases, only the low-side PMOS transistor LPM1 of the low-side PMOS transistors LPM1 and LPM2 is in the on-state, thus the driving capability is suppressed, the slope of the low-side gate voltage LG is decreased and thus the slew rate of the switch voltage Vsw is decreased. Furthermore, when the switch voltage Vsw reaches the ground potential, both the low-side PMOS transistors LPM1 and LPM2 are brought into the on-state, thus the driving capability is increased and thus the slope of the low-side gate voltage LG is increased. Therefore, a time (t13 to t14) until the low-side gate voltage LG reaches the power supply voltage VCC is decreased. In other words, in the present embodiment, a decrease in the efficiency can be suppressed while the self-turning on of the high-side transistor HM is being suppressed.

### <Configuration of Low-Side Drive Unit>

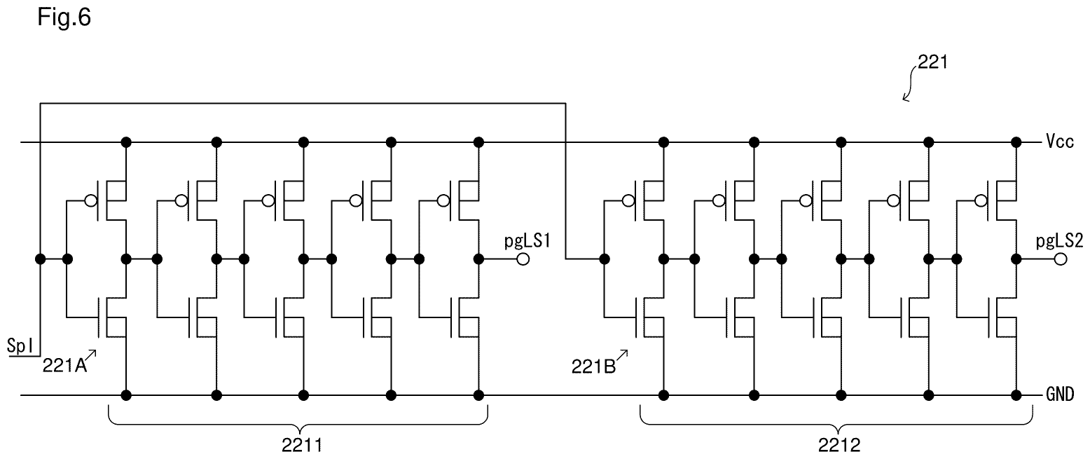

Here, FIG. 6 is a diagram showing a configuration example of the first low-side drive unit 221. The first low-side drive unit 221 includes: a first low-side gate signal generation unit 2211 which generates the gate signal pgLS1 based on the low-side control signal Spl; and a second low-side gate signal generation unit 2212 which generates the gate signal pgLS2 based on the low-side control signal Spl.

The first low-side gate signal generation unit 2211 is formed with inverters 221A in five stages. The inverters 221A are formed with PMOS transistors and NMOS transistors which are connected in series between the power supply voltage VCC and the ground potential. The low-side control signal Spl is input to the inverter 221A in the first stage, and the gate signal pgLS1 is output from the inverter 2121A in the final stage.

The second low-side gate signal generation unit 2212 is formed with inverters 221B in five stages. The inverters 221B are formed with PMOS transistors and NMOS transistors which are connected in series between the power supply voltage VCC and the ground potential. The low-side control signal Spl is input to the inverter 221B in the first stage, and the gate signal pgLS2 is output from the inverter 221B in the final stage.

The number of stages of each of the inverters 221A and the inverters 221B is not limited to five.

The configuration of the second low-side drive unit 222 is obtained by replacing, in the configuration shown in FIG. 6, the low-side control signal Spl with the low-side control signal Snl and the gate signals pgLS1 and pgLS2 with the gate signals ngLS1 and ngLS2.

In order to provide a delay in the gate signals pgLS1 and pgLS2, in the low-side gate signal generation units 2211 and 2212, the size of the NMOS transistor in the inverter 221B in the first stage is decreased beyond the size of the NMOS transistor in the inverter 221A in the first stage, and thus the on-resistance is adjusted. In the inverters 221A and 221B on the side of the subsequent stages, in order to secure the driving capability, it is necessary to increase the size of the transistors, and thus it is difficult to adjust the on-resistance, with the result that the size of the inverter in the first stage is adjusted. For example, in addition to the first stage, the size of the transistor in the inverter in the second stage may be adjusted.

### 2. Second Embodiment

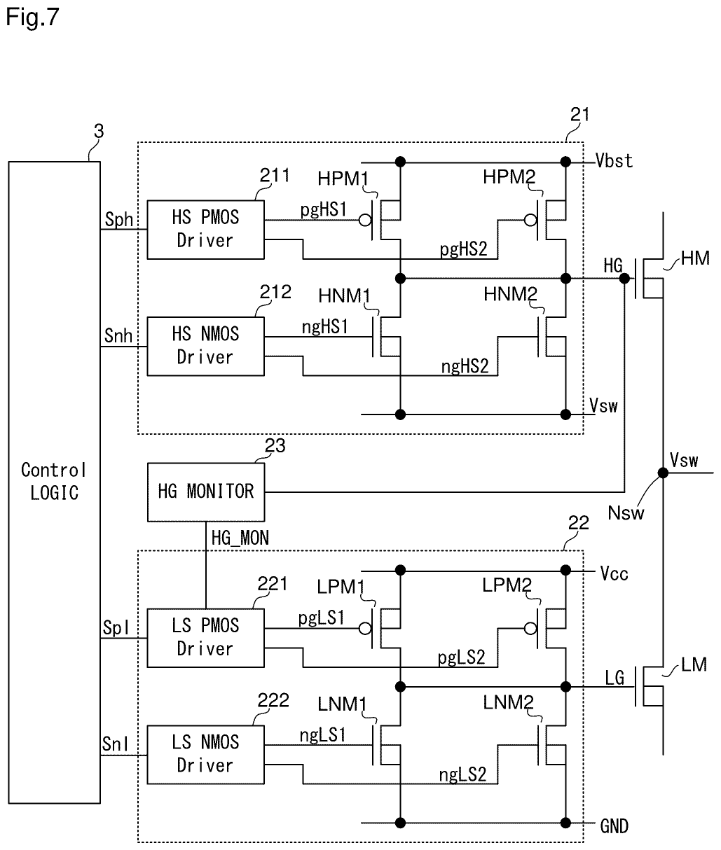

FIG. 7 is a diagram showing the configuration of a gate drive circuit 2 according to a second embodiment of the present disclosure. The gate drive circuit 2 shown in FIG. 7 differs from the configuration in the first embodiment (FIG. 2) described above in that the gate drive circuit 2 further includes a high-side gate voltage monitoring unit 23. In the second embodiment, as in the first embodiment, a delay is provided in gate signals pgHS1 and pgHS2 by the configuration of a first high-side drive unit 211 in a high-side pre-driver 21. In this way, when a high-side transistor HM is turned on (as long as the normal operation is performed), a decrease in the efficiency can be suppressed while the self-turning on of a low-side transistor is being suppressed.

### <Configuration of High-Side Gate Voltage Monitoring Unit>>

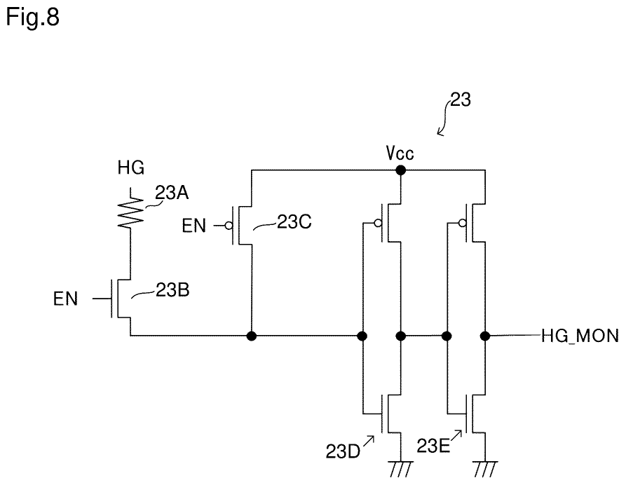

FIG. 8 a diagram showing a configuration example of the high-side gate voltage monitoring unit 23. The high-side gate voltage monitoring unit 23 shown in FIG. 8 includes a resistor 23A, switches 23B and 23C and inverters 23D and 23E. The switch 23B is formed with an NMOS transistor. The switch 23C is formed with a PMOS transistor.

One end of the resistor 23A is connected to the gate of the high-side transistor HM. The other end of the resistor 23A is connected via the switch 23B to the input end of the inverter 23D. The inverters 23D and 23E include PMOS transistors and NMOS transistors which are connected in series between a power supply voltage VCC and a ground potential. The output end of the inverter 23D is connected to the input end of the inverter 23E. The switch 23C is connected between the application end of the power supply voltage VCC and the input end of the inverter 23D.

The switches 23B and 23C are controlled by an enable signal EN. When the enable terminal EN is low, the switch 23B is in an off-state, the switch 23C is in an on-state and thus the PMOS transistors in the inverters 23D and 23E are in an off-state. In this way, the high-side gate voltage monitoring unit 23 is disabled.

On the other hand, when the enable signal EN is high, the switch 23B is in the on-state, the switch 23C is in the off-state and thus the high-side gate voltage monitoring unit 23 is enabled. In this case, since a high-side gate voltage HG is with reference to a switch voltage Vsw, when the switch voltage Vsw is low and the high-side gate voltage HG is low, a monitor signal HG_MOM output from the inverter 23E is low.

### <Configuration of Low-Side Drive Unit>

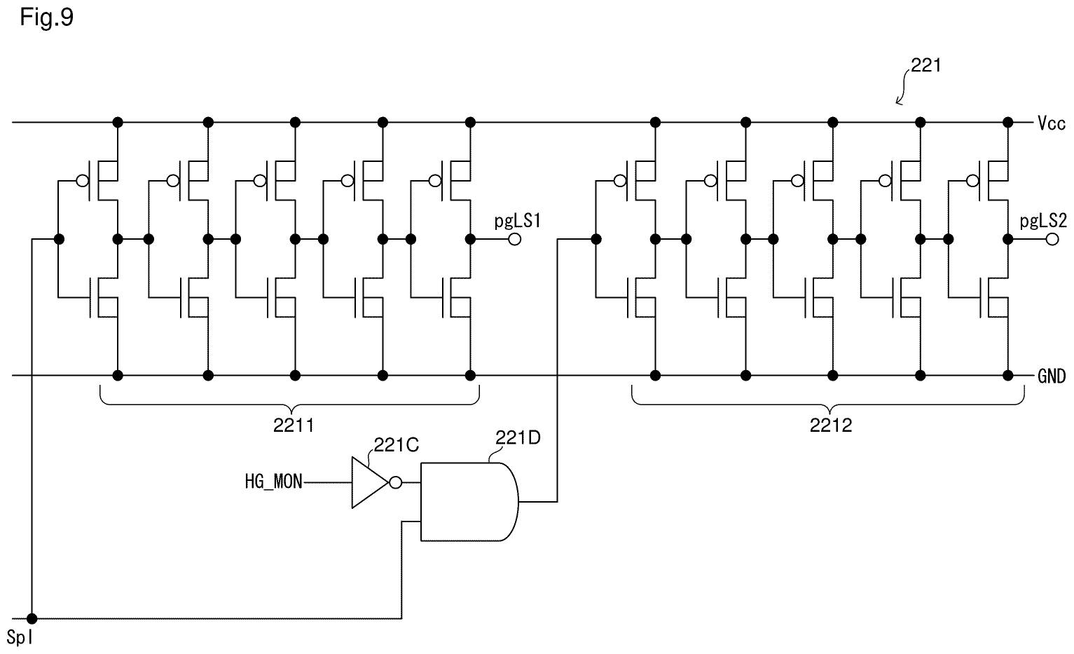

FIG. 9 a diagram showing a configuration example of a first low-side drive unit 221 in the second embodiment. The first low-side drive unit 221 shown in FIG. 9 includes: a first low-side gate signal generation unit 2211 which generates a gate signal pgLS1 based on a low-side control signal Spl; and a second low-side gate signal generation unit 2212 which generates a gate signal pgLS2 based on the low-side control signal Spl. The low-side gate signal generation units 2211 and 2212 are the same as the configuration shown in FIG. 6 described above.

The first low-side drive unit 221 in the present embodiment further includes an inverter 221C and an AND circuit 221D. The monitor signal HG_MOM is input to the inverter 221C. The output of the inverter 221C is input to one input end of the AND circuit 221C, and the low-side control signal Spl is input to the other input end. The output of the AND circuit 221D is input to the second low-side gate signal generation unit 2212.

In the configuration described above, when the low-side control signal Spl rises high, the gate signal pgLS1 first falls low. Then, when the monitor signal HG_MOM falls low, the output of the AND circuit 221D rises high, and the gate signal pgLS2 falls low. Hence, a delay can be provided in the gate signal pgLS2 with respect to the gate signal pgLS1.

<Operation when Low-Side Transistor is Turned on (During Reverse Flow Operation)>

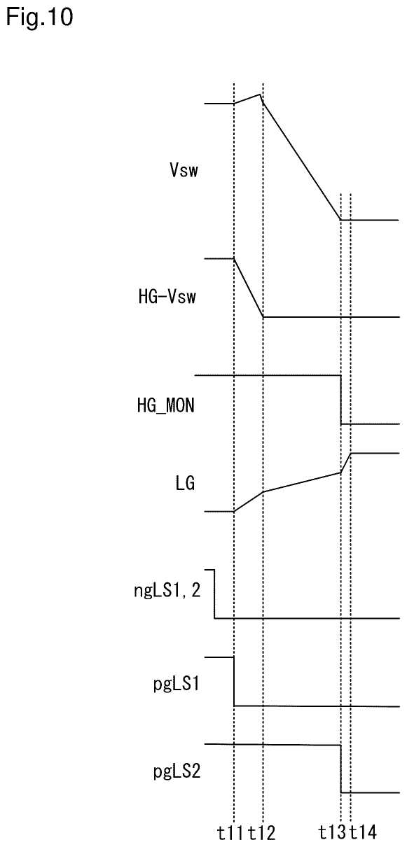

FIG. 10 is a timing chart showing an operation when the high-side transistor HM is turned off and a low-side transistor LM is turned on in the second embodiment. FIG. 10 shows a case where the reverse flow operation is performed.

The timing chart shown in FIG. 10 differs from that in FIG. 5 (first embodiment) in a monitor signal HG_MON. In FIG. 10, the low-side control signal Spl is first switched high, and thus at a timing t11, the gate signal pgLS1 is switched low.

Thereafter, when the switch voltage Vsw is lowered to approach the ground potential, the monitor signal HG_MON is switched low by the high-side gate voltage monitoring unit 23. Then, the gate signal pgLS2 is switched low. As described above, even in the present embodiment, a delay is provided in the gate signals pgLS1 and pgHS2, and thus as in the first embodiment, a decrease in the efficiency can be suppressed while the self-turning on of the high-side transistor is being suppressed.

<Operation when Low-Side Transistor is Turned on (During Normal Operation)>

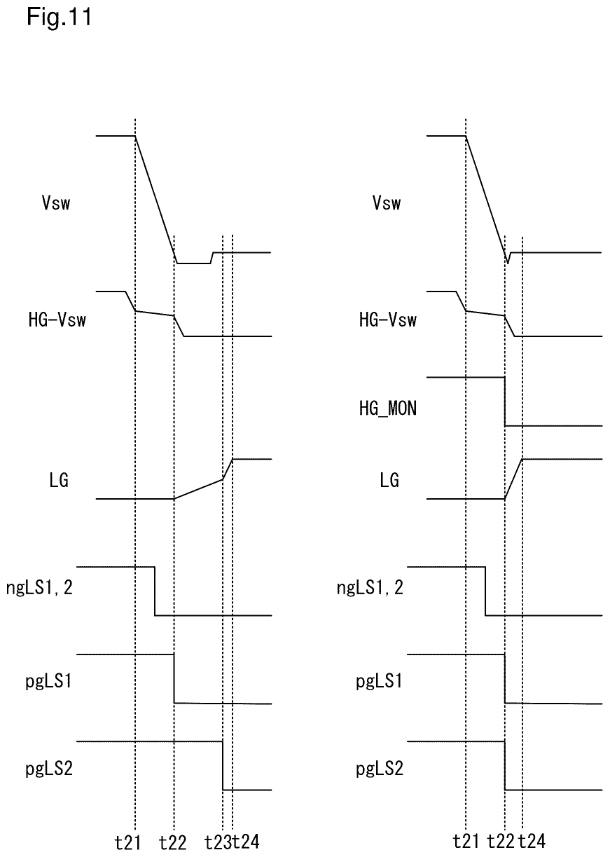

FIG. 11 is a timing chart showing an operation when the high-side transistor HM is turned off and the low-side transistor LM is turned on in the embodiment of the present disclosure. FIG. 11 shows a case where the normal operation is performed.

The left side of FIG. 11 shows the operation in the first embodiment. In this case, the discharge of the gate of the high-side transistor HM is first started by the high-side pre-driver 21, and thus the high-side gate voltage HG starts to decrease.

The switch voltage Vsw starts to decrease from a timing t21. As the high-side gate voltage HG decreases, the on-resistance of the high-side transistor HM increases, and thus a voltage drop in the high-side transistor HM increases, with the result that the switch voltage Vsw decreases.

Then, at a timing t22 when the switch voltage Vsw approaches the ground potential, the gate signal pgLS1 is switched low. In this way, the low-side PMOS transistor LPM1 is turned on, and thus the low-side gate voltage LG starts to rise. Thereafter, at a timing t23, the gate signal pgLS2 is switched low. In this way, the low-side PMOS transistor LPM2 is turned on, and thus the low-side gate voltage LG further continues to rise to reach the power supply voltage VCC (timing t24).

As described above, when the low-side transistor LM is turned on during the normal operation, after the transfer of the switch voltage Vsw, the low-side gate voltage LG starts to rise, with the result that the slope of the low-side gate voltage LG is not related to the slew rate of the switch voltage Vsw. Hence, in the first embodiment, the gate signal pgLS2 is constantly delayed with respect to the gate signal pgLS1, and thus a time (t22 to t24) until the low-side gate voltage LG reaches the power supply voltage VCC is increased, with the result that the efficiency is decreased. A rise in the low-side gate voltage LG is delayed, and thus a rise in the switch voltage Vsw is delayed.

On the other hand, the right side of FIG. 11 shows the operation in the second embodiment. In this case, at a timing t22 when the switch voltage Vsw approaches the ground potential, the monitor signal HG_MON is switched low. Hence, the gate signal pgLS2 is switched low with almost no delay with respect to the gate signal pgLS1. In this way, after the timing t22, the low-side gate voltage LG rises in a state where the driving capability is high, and thus the slope of the low-side gate voltage LG is increased. Therefore, the time (t22 to t24) until the low-side gate voltage LG reaches the power supply voltage VCC is decreased, with the result that the decrease in the efficiency can be suppressed.

As described above, in the second embodiment, a decrease in the efficiency can be suppressed both during the reverse flow operation and the normal operation.

### 3. Others

In addition to the embodiments described above, various technical features disclosed in the present specification can be variously changed without departing from the spirit of its technical creation. In other words, the embodiments described above should be considered to be illustrative in all respects and not restrictive, and it should be understood that the technical scope of the present invention is not limited to the embodiments described above, and meaning equivalent to the scope of claims and all changes belonging to the scope are included therein.

For example, the present disclosure is not limited to DC/DC converters, and can also be applied to the driving of a transistor in an inverter circuit or the like which performs DC/AC conversion.

### 4. Additional Description

As described above, a first current generation circuit (2) according to an aspect of the present disclosure is a gate drive circuit configured to drive a half bridge in which a high-side transistor to be driven (HM) and a low-side transistor to be driven (LM) are connected in series between a power supply voltage (Vin) and a ground potential, the gate drive circuit includes: a high-side pre-driver (21) configured to drive the gate of the high-side transistor to be driven; and a low-side pre-driver (22) configured to drive the gate of the low-side transistor to be driven, the high-side pre-driver includes a first high-side transistor (HPM1) and a second high-side transistor (HPM2), the low-side pre-driver includes a third high-side transistor (LPM1) and a fourth high-side transistor (LPM2) and a delay is provided in at least one of a time period between a first gate signal (pgHS1) configured to turn on the first high-side transistor and a second gate signal (pgHS2) configured to turn on the second high-side transistor and a time period between a third gate signal (pgLS1) configured to turn on the third high-side transistor and a fourth gate signal (pgLS2) configured to turn on the fourth high-side transistor (first configuration).

In the first configuration, the high-side pre-driver (21) may include a high-side drive unit (211) configured to generate the first gate signal (pgHS1) and the second gate signal (pgHS2) based on a high-side control input signal (Sph) (second configuration).

In the second configuration, the high-side drive unit (211) may include a first high-side gate signal generation unit (2111) configured to include a plurality of first inverters (211A) to generate the first gate signal (paHS1) and a second high-side gate signal generation unit (2112) configured to include a plurality of second inverters (211B) to generate the second gate signal (pgHS2), and at least one of the second inverters in the second high-side gate signal generation unit may be smaller in the size of a transistor than at least one of the first inverters in the first high-side gate signal generation unit (third configuration).

In the third configuration, the second inverter (211B) in a first stage included in the second high-side gate signal generation unit (2112) may be smaller in the size of the transistor than the first inverter (211A) in a first stage included in the first high-side gate signal generation unit (2111) (fourth configuration).

In any one of the first to fourth configurations, the low-side pre-driver (22) may include a low-side drive unit (221) configured to generate the third gate signal (pgLS1) and the fourth gate signal (pgLS2) based on a low-side control input signal (Sp1) (fifth configuration).

In the fifth configuration, the low-side drive unit (221) may include a first low-side gate signal generation unit (2211) configured to include a plurality of third inverters (221A) to generate the third gate signal (pgLS1) and a second low-side gate signal generation unit (2212) configured to include a plurality of fourth inverters (221B) to generate the fourth gate signal (pgLS2), and at least one of the fourth inverters in the second low-side gate signal generation unit may be smaller in the size of a transistor than at least one of the third inverters in the first low-side gate signal generation unit (sixth configuration).

In the sixth configuration, the fourth inverter (221B) in a first stage included in the second low-side gate signal generation unit (2212) may be smaller in the size of the transistor than the third inverter (221A) in a first stage included in the first low-side gate signal generation unit (2211) (seventh configuration).

In any one of the first to seventh configurations, the gate drive circuit may further include: a monitoring unit (23) configured to monitor whether a gate voltage (HG) of the high-side transistor to be driven (HM) is low and whether a voltage (Vsw) at a node (Nsw) where the high-side transistor to be driven and the low-side transistor to be driven are connected is low, and the fourth gate signal (pgLS2) may be generated based on a monitor signal (HG_MON) output from the monitoring unit (eighth configuration).

In the eighth configuration, the monitoring unit (23) may include a resistor (23A) configured to include a first end connected to the gate of the transistor to be driven (HM) and an inverter stage (23D, 23E) configured to include an input end connected to a second end of the resistor (ninth configuration).

### <<Second Disclosed Technique>>

### <Configuration of Semiconductor Device>

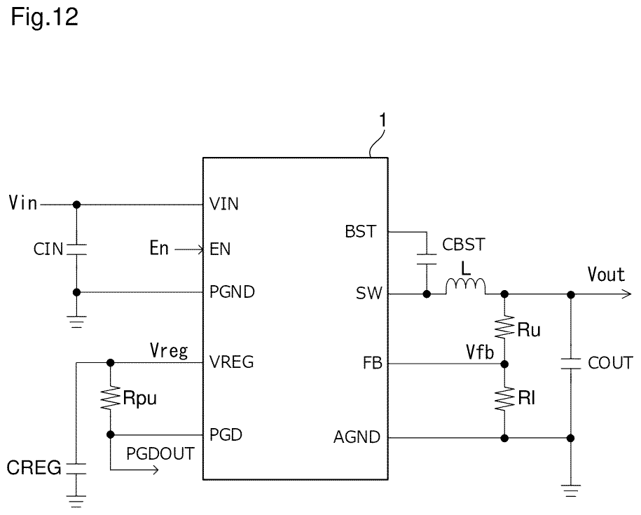

FIG. 12 is a diagram showing the configuration of a semiconductor device 1 in an illustrative embodiment of the present disclosure. The semiconductor device 1 is a device obtained by packaging a power supply IC which has a DC/DC converter function. As shown in FIG. 12, the semiconductor device 1 includes, as external terminals for establishing electrical connection with the outside, a VIN (input voltage) terminal, an EN (enable) terminal, a PGND (power ground) terminal, a VREG (constant voltage) terminal, a PGD (power good) terminal, a BST (bootstrap) terminal, a SW (switch) terminal, an FB (feedback) terminal and an AGND (analog ground) terminal.

An input voltage Vin can be applied to the VIN terminal. A ground potential can be applied to the PGND terminal. An input capacitor CIN is connected between the application end of the input voltage Vin and the application end of the ground potential. The semiconductor device 1 includes an unillustrated upper switching element and an unillustrated lower switching element. The upper switching element and the lower switching element each are formed with an NMOS transistor (N-channel MOSFET (metal-oxide-semiconductor field effect transistor)). The upper switching element and the lower switching element are connected in series between the VIN terminal and the PGND terminal. A node where the upper switching element and the lower switching element are connected is connected to the SW terminal.

The SW terminal is connected to one end of an inductor L. The other end of the inductor L is connected to one end of an output capacitor COUT. The other end of the output capacitor Cout and the AGND terminal are connected to the application end of the ground potential. An output voltage Vout is generated at the other end of the inductor L.

Voltage dividing resistors Ru and R1 are connected in series between the other end of the inductor L and the AGND terminal. A node where the voltage dividing resistors Ru and R1 are connected is connected to the FB terminal. A feedback voltage Vfb which is generated by dividing the output voltage Vout with the voltage dividing resistors Ru and R1 is applied to the FB terminal. The semiconductor device 1 includes an unillustrated feedback control unit. The feedback control unit performs, based on the feedback voltage Vfb, switching control on the upper switching element and the lower switching element. In this way, the output voltage Vout is controlled to have a predetermined voltage value. The feedback control unit includes an error amplifier, a control logic unit, a driver and the like.

A bootstrap capacitor CBST is connected between the BST terminal and the SW terminal. The bootstrap capacitor CBST is charged, and thus the upper switching element formed with the NMOS transistor can be brought into an on-state.

The upper switching element, the lower switching element and the feedback control unit are provided in the semiconductor device 1 by being integrated into the power supply IC described above.

A configuration related to the EN terminal, the VREG terminal and the PGD terminal will be described later.

### <Internal Power Supply>

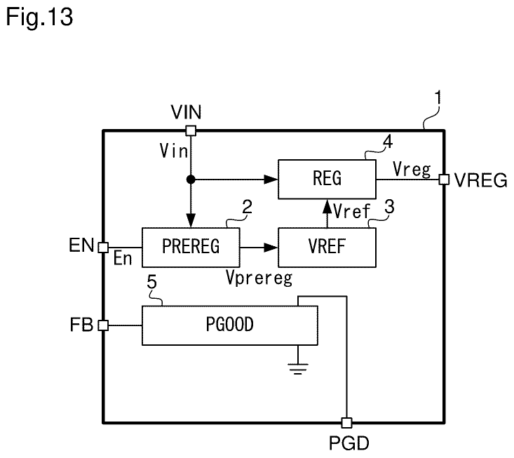

FIG. 13 is a diagram showing a part of an internal configuration of the semiconductor device 1. As shown in FIG. 13, the semiconductor device 1 includes a pre-regulator (PREREG) 2, a reference voltage generation unit 3 and a regulator (REG) 4, and the configuration thereof is integrated into the power supply IC.

The pre-regulator 2 generates a first power supply voltage Vprereg based on the input voltage Vin applied to the VIN terminal. The first power supply voltage Vprereg is a constant voltage.

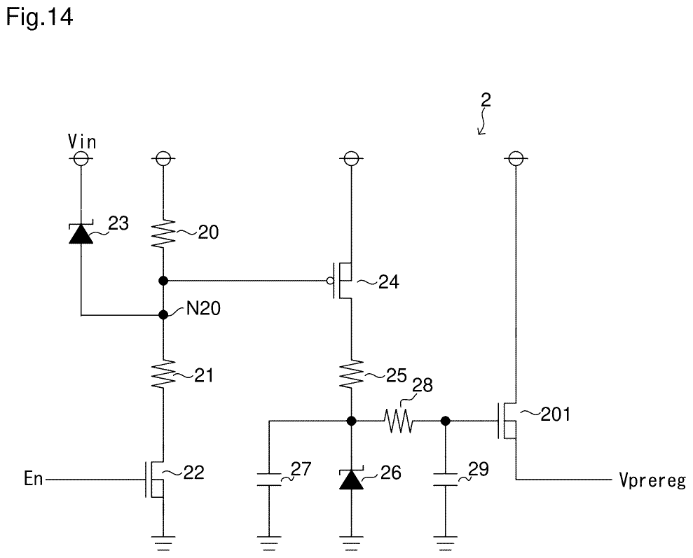

Here, FIG. 14 is a diagram showing a configuration example of the pre-regulator 2. The pre-regulator 2 includes voltage dividing resistors 20 and 21, an NMOS transistor 22, a Zener diode 23, a PMOS transistor (P-channel MOSFET) 24, a resistor 25, a Zener diode 26, a capacitor 27, a resistor 28, a capacitor 29 and an NMOS transistor 201.

The voltage dividing resistors 20 and 21 are connected in series between the application end of the input voltage Vin and the drain of the NMOS transistor 22. The source of the NMOS transistor 22 is connected to the application end of the ground potential. The gate of the NMOS transistor 22 is driven by an enable signal En applied to the EN terminal (FIG. 13).

The anode of the Zener diode 23 is connected to a node N20 to which voltage dividing resistors 20 and 21 are connected. The cathode of the Zener diode 23 is connected to the application end of the input voltage Vin. The Zener diode 23 clamps the voltage at the node N20 to suppress an excessive decrease.

The node N20 is connected to the gate of the PMOS transistor 24. The source of the PMOS transistor 24 is connected to the application end of the input voltage Vin. The drain of the PMOS transistor 24 is connected to one end of the resistor 25. The other end of the resistor 25 is connected to the cathode of the Zener diode 26. The anode of the Zener diode 26 is connected to the application end of the ground potential.

The cathode of the Zener diode 26 is connected to one end of the capacitor 27. The other end of the capacitor 27 is connected to the application end of the ground potential. The cathode of the Zener diode 26 is connected to one end of the resistor 28. The other end of the resistor 28 is connected to one end of the capacitor 29. The other end of the capacitor 29 is connected to the application end of the ground potential. A low-pass filter is formed with the resistor 28 and the capacitor 29.

The other end of the resistor 28 is connected to the gate of the NMOS transistor 201. The drain of the NMOS transistor 201 is connected to the application end of the input voltage Vin. The first power supply voltage Vprereg is generated at the source of the NMOS transistor 201.

In the configuration described above, when the enable signal En is low, the NMOS transistor 22 is in an off-state, and thus the input voltage Vin is applied to the gate of the PMOS transistor 24. In this way, the PMOS transistor 24 is in an off-state, and thus the first power supply voltage Vprereg is not generated.

On the other hand, when the enable signal En is high, the NMOS transistor 22 is in an on-state, and thus a voltage obtained by dividing the input voltage Vin with the voltage dividing resistors 20 and 21 is generated at the node N20, with the result that the PMOS transistor 24 is in an on-state. In this way, the first power supply voltage Vprereg is generated as Vprereg=Vz−Vgs. However, the Vz is the Zener voltage of the Zener diode 26, and the Vgs is the gate-source voltage of the NMOS transistor 201.

With reference back to FIG. 13, the reference voltage generation unit 3 generates the reference voltage Vref based on the first power supply voltage Vprereg. The reference voltage generation unit 3 is formed with, for example, a bandgap reference. The reference voltage Vref is used, for example, for the generation of a second power supply voltage Vreg in the regulator 4.

The regulator 4 generates the second power supply voltage Vreg based on the input voltage Vin. The regulator 4 is formed with, for example, a LDO (Low Dropout). In this case, the reference voltage Vref is input to an error amplifier in the LDO. The second power supply voltage Vreg is generated at the VREG terminal. As shown in FIG. 12, the VREG terminal is connected to a capacitor CREG. The second power supply voltage Vreg is supplied to the parts of the power supply IC. The second power supply voltage Vreg is supplied to, for example, a power good circuit 5 which will be described later.

The voltage values of the first power supply voltage Vprereg and the second power supply voltage Vreg may be the same as or different from each other.

### <Power Good Circuit>

As shown in FIG. 13, the semiconductor device 1 includes the power good circuit 5. The power good circuit 5 is integrated into the power supply IC.

The power good circuit 5 is connected between the PGD terminal and the application end of the ground potential. As shown in FIG. 12, a pull-up resistor Rpu is connected between the PGD terminal and the VREG terminal. In other words, the PGD terminal is pulled up to the second power supply voltage Vreg.

The power good circuit 5 includes a switch (output transistor) which is connected between the PGD terminal and the application end of the ground potential and is not shown in FIG. 13. When the switch is in an on-state, a flag signal PGDOUT (FIG. 12) output from the PGD terminal is low whereas when the switch is in an off-state, the flag signal PGDOUT is high.

In the power good circuit 5, when the power supply IC is started up to cause the output voltage Vout to rise, and then the output voltage Vout reaches a voltage value which is set, this is detected based on the feedback voltage Vfb generated at the FB terminal, and a high-level flag signal PGDOUT is output. With the flag signal PGDOUT, it is possible to notify the outside that the output voltage Vout output from a power supply circuit (DC/DC converter) has normally rosed.

### Comparative Example

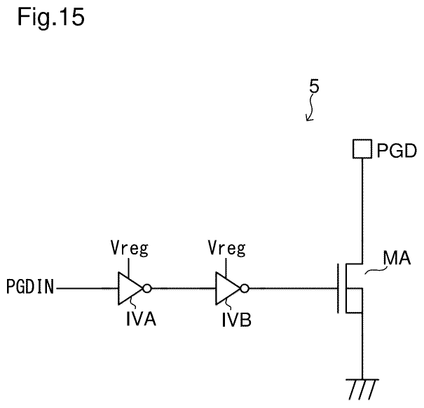

FIG. 15 is a diagram showing the configuration of a power good circuit 5 in a comparative example. The comparative example will be described for comparison with the embodiments of the present disclosure to be described later. Problems will become clear by describing the comparative example.

The power good circuit 5 shown in FIG. 15 includes an output transistor MA and inverters IVA and IVB. The output transistor MA is formed with an NMOS transistor. The drain of the output transistor MA is connected to a PGD terminal. The source of the output transistor MA is connected to the application end of a ground potential.

The input end of the inverter IVA is connected to the application end of a control input signal PGDIN. The control input signal PGDIN is a signal which is generated inside the power good circuit 5. The output end of the inverter IVA is connected to the input end of the inverter IVB. The output end of the inverter IVB is connected to the gate of the output transistor MA. In this way, the control input signal PGDIN is logically inverted by each of the inverters IVA and IVB and is input to the gate of the output transistor MA.

Each of the inverters IVA and IVB includes a PMOS transistor and an NMOS transistor which are not shown in the figure. The source of the PMOS transistor is connected to the application end of a second power supply voltage Vreg. The drain of the PMOS transistor is connected to the drain of the NMOS transistor. The source of the NMOS transistor is connected to the application end of the ground potential. The gate of the PMOS transistor and the gate of the NMOS transistor are connected to the input end of the inverter. A node where the drain of the PMOS transistor and the drain of the NMOS transistor are connected is connected to the output end of the inverter. In other words, the inverters IVA and IVB use the second power supply voltage Vreg as a power supply voltage.

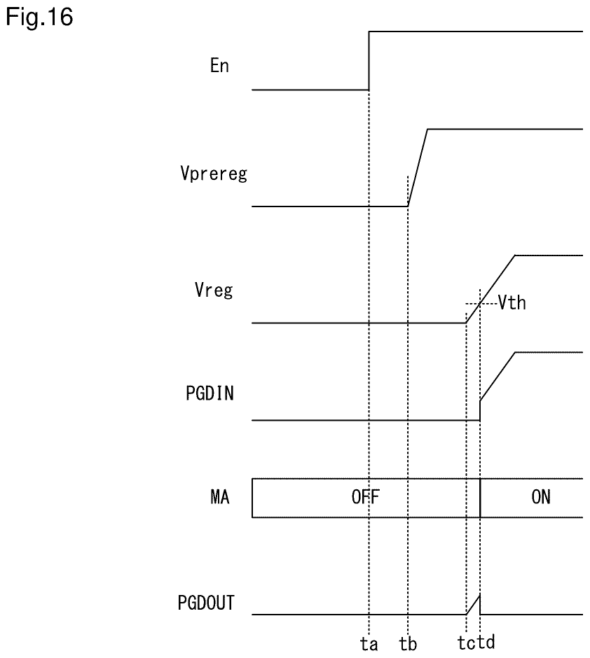

FIG. 16 is a timing chart showing an operation of the power good circuit 5 in the comparative example when the power supply IC described above is started up. FIG. 16 shows, sequentially from the uppermost stage, an enable signal En, a first power supply voltage Vprereg, a second power supply voltage Vreg, the control input signal PGDIN, the on-state and the off-state of the output transistor MA and a flag signal PGDOUT.

The enable signal En is switched from a low level indicating being disabled to a high level indicating being enabled (timing ta). Then, a pre-regulator 2 is started up, and thus the first power supply voltage Vprereg starts to rise (timing tb). Thereafter, a reference voltage generation unit 3 is started up, and thus a regulator 4 is started up by a reference voltage Vref. Here, the second power supply voltage Vreg starts to rise (timing tc). In other words, the pre-regulator 2, the reference voltage generation unit 3 and the regulator 4 are started up in this order.

Until the second power supply voltage Vreg reaches a threshold voltage Vth (Vreg=low level), the control input signal PGDIN is low (the Vreg reaches the Vth at a timing td). The threshold voltage Vth is a threshold voltage both for the inverters IVA and IVB and for the output transistor MA.

When second power supply voltage Vreg<threshold voltage Vth, the outputs of the inverters IVA and IVB are brought into an indeterminate logic state, and thus the output transistor MA is brought into an off-state. Here, the PGD terminal is pulled up to the second power supply voltage Vreg, and thus until the second power supply voltage Vreg reaches the threshold voltage Vth, the second power supply voltage Vreg continues to rise at the flag signal PGDOUT (between the timing tc and the timing td).

When the second power supply voltage Vreg exceeds the threshold voltage Vth, the control input signal PGDIN is switched high, and thus a high-level signal is input to the gate of the output transistor MA, with the result that the output transistor MA is brought into the on-state. In this way, the flag signal PGDOUT falls low.

The second power supply voltage Vreg rises to start up an unillustrated control logic unit, and thus a DC/DC converter function in a semiconductor device 1 is stared up. In this way, when the output voltage Vout rises to reach a voltage value which is set, the control input signal PGDIN is switched low. Hence, the output transistor MA is brought into the off-state, and thus the flag signal PGDOUT is switched high.

As described above, in the power good circuit 5 in the comparative example, when the power supply IC is started up, the output transistor MA cannot be brought into the on-state, with the result that the flag signal PGDOUT is disadvantageously raised. In order to solve this problem, the embodiments of the present disclosure which will be described below are implemented.

### First Embodiment

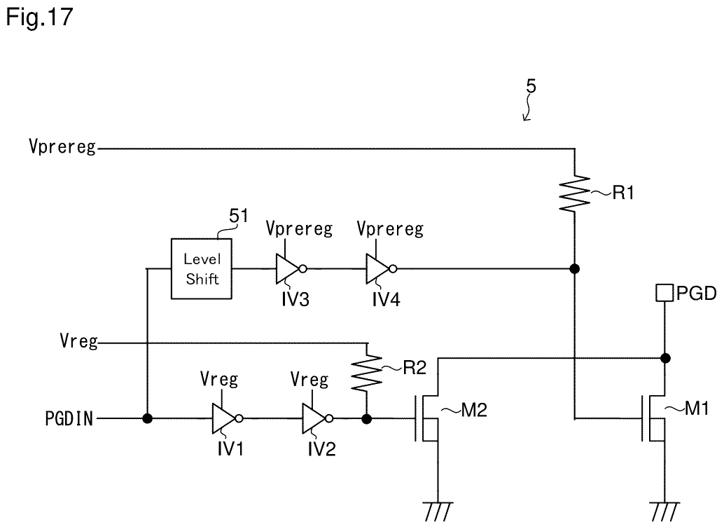

FIG. 17 is a diagram showing the configuration of a power good circuit 5 according to the first embodiment of the present disclosure. The power good circuit 5 shown in FIG. 17 includes an output transistor M1, an output transistor M2, inverters IV1 to IV4, pull-up resistors R1 and R2 and a level-shift circuit 51.

The output transistor M1 is formed with an NMOS transistor. The drain of the output transistor M1 is connected to a PGD terminal. The source of the output transistor M1 is connected to the application end of a ground potential. The pull-up resistor R1 is connected between the gate of the output transistor M1 and the application end of a first power supply voltage Vprereg.

The input end of the level-shift circuit 51 is connected to the application end of a control input signal PGDIN. The output end of the level-shift circuit 51 is connected to the input end of the inverter IV3. The output end of the inverter IV3 is connected to the input end of the inverter IV4. The output end of the inverter IV4 is connected to the gate of the output transistor M1. The level of the control input signal PGDIN is converted by the level-shift circuit 51 from a second power supply voltage Vreg to the first power supply voltage Vprereg. The control input signal PGDIN the level of which has been converted is logically inverted by each of the inverters IV3 and IV4 and is input to the gate of the output transistor M1. In the present embodiment, the first power supply voltage Vprereg differs from the second power supply voltage Vreg in the voltage value (for example, Vprereg=4.5V and Vreg=3V).

The inverters IV3 and IV4 have the same configuration as the inverters IVA and IVB in the comparative example described above except that the first power supply voltage Vprereg is used as the power supply voltage. In other words, the inverters IV3 and IV4 include a PMOS transistor and an NMOS transistor which are not shown in the figure.

The drain of the output transistor M2 is connected to the PGD terminal. The source of the output transistor M2 is connected to the application end of the ground potential.

The input end of the inverter IV1 is connected to the application end of the control input signal PGDIN. The output end of the inverter IV1 is connected to the input end of the inverter IV2. The output end of the inverter IV2 is connected to the gate of the output transistor M2. In this way, the control input signal PGDIN is logically inverted by each of the inverters IV1 and IV2 and is input to the gate of the output transistor M2.

The inverters IV1 and IV2 use the second power supply voltage Vreg as the power supply voltage, and have the same configuration as the inverters IVA and IVB in the comparative example described above.

The pull-up resistor R2 is connected between the gate of the output transistor M2 and the application end of the second power supply voltage Vreg.

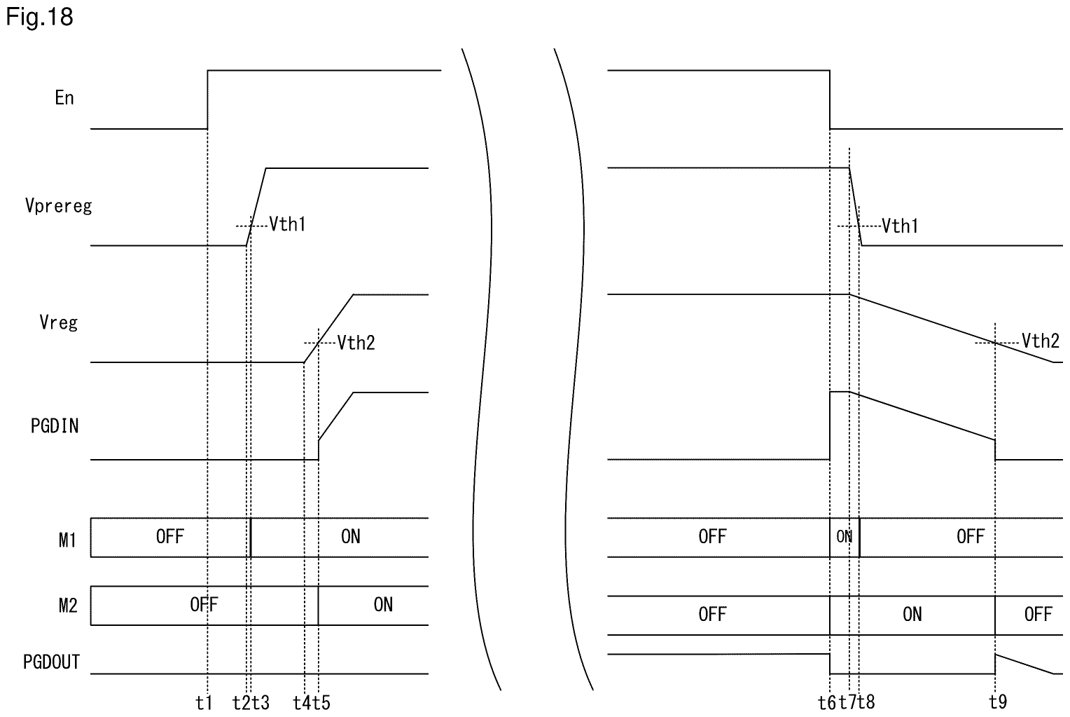

FIG. 18 is a timing chart showing operations of the power good circuit 5 according to the first embodiment when the power supply IC is started up and when the power supply IC is shut down. FIG. 18 shows, sequentially from the uppermost stage, an enable signal En, the first power supply voltage Vprereg, the second power supply voltage Vreg, the control input signal PGDIN, the on-state and the off-state of the output transistors M1 and M2 and a flag signal PGDOUT.

The enable signal En is first switched from low to high (timing t1). Then, the first power supply voltage Vprereg starts to rise (timing t2). Then, the first power supply voltage Vprereg reaches a threshold voltage Vth1 (timing t3). The threshold voltage Vth1 is a threshold voltage both for the output transistor M1 and for the inverters IV3 and IV4.

When the first power supply voltage Vprereg reaches the threshold voltage Vth1, the first power supply voltage Vprereg is applied via the pull-up resistor R1 to the gate of the output transistor M1, and thus the output transistor M1 is switched from the off-state to the on-state.

Here, when the second power supply voltage Vreg is low (equal to or less than a threshold voltage Vth2), the level-shift circuit 51 outputs a high-level signal as an initial value. Until the first power supply voltage Vprereg reaches the threshold voltage Vth1, the outputs of the inverters IV3 and IV4 are brought into an indeterminate logic state, but when the first power supply voltage Vprereg reaches the threshold voltage Vth1, the output of the inverter IV4 is determined to be high, and thus the output transistor M1 is brought into the on-state.

Until the first power supply voltage Vprereg reaches the threshold voltage Vth1 (timings t2 to t3), the outputs of the inverters IV3 and IV4 are brought into an indeterminate logic state, but the first power supply voltage Vprereg is applied to the gate of the output transistor M1 by the pull-up resistor R1, and thus the voltage level of the gate of the output transistor M1 is determined.

Thereafter, the second power supply voltage Vreg starts to rise (timing t4). Then, the second power supply voltage Vreg reaches the threshold voltage Vth2 (timing t5). The threshold voltage Vth2 is a threshold voltage both for the output transistor M2 and for the inverters IV1 and IV2.

Until the second power supply voltage Vreg reaches the threshold voltage Vth2 (timings t4 to t5), the control input signal PGDIN is low, and thus the outputs of the inverters IV1 and IV2 are brought into an indeterminate logic state. Here, although the second power supply voltage Vreg is applied via the pull-up resistor R2 to the gate of the output transistor M2, the output transistor M2 is in the off-state.

When the second power supply voltage Vreg reaches the threshold voltage Vth2, the control input signal PGDIN is switched high, and thus the output of the inverter IV2 is determined to be high. In this way, the output transistor M2 is switched to the on-state. In other words, here, both the output transistors M1 and M2 are brought into the on-state.

As described above, in the present embodiment, the output transistor M1 has already been brought into the on-state by the first power supply voltage Vprereg until the second power supply voltage Vreg reaches the threshold voltage Vth2, and thus the flag signal PGDOUT output from the PGD terminal is prevented from being raised.

The pull-up resistor R2 which pulls up the gate of the output transistor M2 to the second power supply voltage Vreg does not necessarily need to be provided. However, the pull-up resistor R2 is provided, and thus even when the output of the inverter IV2 is in an indeterminate logic state, the second power supply voltage Vreg can be applied via the pull-up resistor R2 to the gate of the output transistor M2, with the result that the voltage level of the gate of the output transistor M2 can be determined.

When as described above, the power supply IC is started up, and thus the output voltage Vout rises to reach a voltage value which is set, the control input signal PGDIN is switched from high to low. In this way, the levels of the gates of the output transistors M1 and M2 are switched low, and thus both the output transistors M1 and M2 are brought into the off-state. In this way, the flag signal PGDOUT is switched from low to high.

Then, the operation when the power supply IC is shut down will be described. As shown in FIG. 18, the enable signal En falls from high to low (timing t6). Then, the output voltage Vout falls, and thus the control input signal PGDIN is switched from low to high. In this way, both the output transistors M1 and M2 are switched from the off-state to the on-state. Hence, the flag signal PGDOUT is switched from high to low.

Thereafter, the first power supply voltage Vprereg and the second power supply voltage Vreg start to fall (timing t7). Since the capacitor CREG is connected to the VREG terminal, the second power supply voltage Vreg falls more gradually than the first power supply voltage Vprereg.

When the first power supply voltage Vprereg falls to drop below the threshold voltage Vth1, the output transistor M1 is brought into the off-state (timing t8). Here, the second power supply voltage Vreg is equal to or greater than the threshold voltage Vth2, and thus the output transistor M2 is in the on-state. Hence, the flag signal PGDOUT is kept low.

Thereafter, the second power supply voltage Vreg drops below the threshold voltage Vth2, the control input signal PGDIN is switched from high to low (timing t9). In this way, the output transistor M2 is brought into the off-state. Here, both the output transistors M1 and M2 are brought into the off-state.

As described above, in the present embodiment, the output transistors M1 and M2 can be controlled in a state where at least one of the first power supply voltage Vprereg and the second power supply voltage Vreg are started up (during a period from the timing t3 to the timing t9).

### Second Embodiment

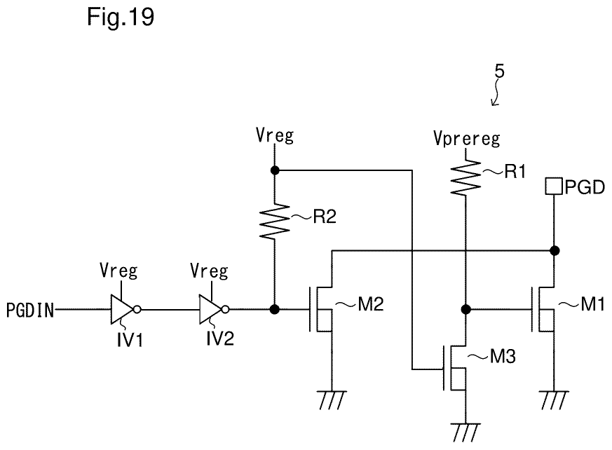

FIG. 19 is a diagram showing the configuration of a power good circuit 5 according to the second embodiment of the present disclosure. The power good circuit 5 shown in FIG. 19 differs from the configuration (FIG. 17) in the first embodiment in that the power good circuit 5 further includes a control transistor M3. In the configuration shown in FIG. 19, the level-shift circuit 51 and the inverters IV3 and IV4 are not provided.

The control transistor M3 is formed with an NMOS transistor. The drain of the control transistor M3 is connected to the gate of an output transistor M1. The source of the control transistor M3 is connected to the application end of a ground potential. The gate of the control transistor M3 is connected to the application end of a second power supply voltage Vreg.

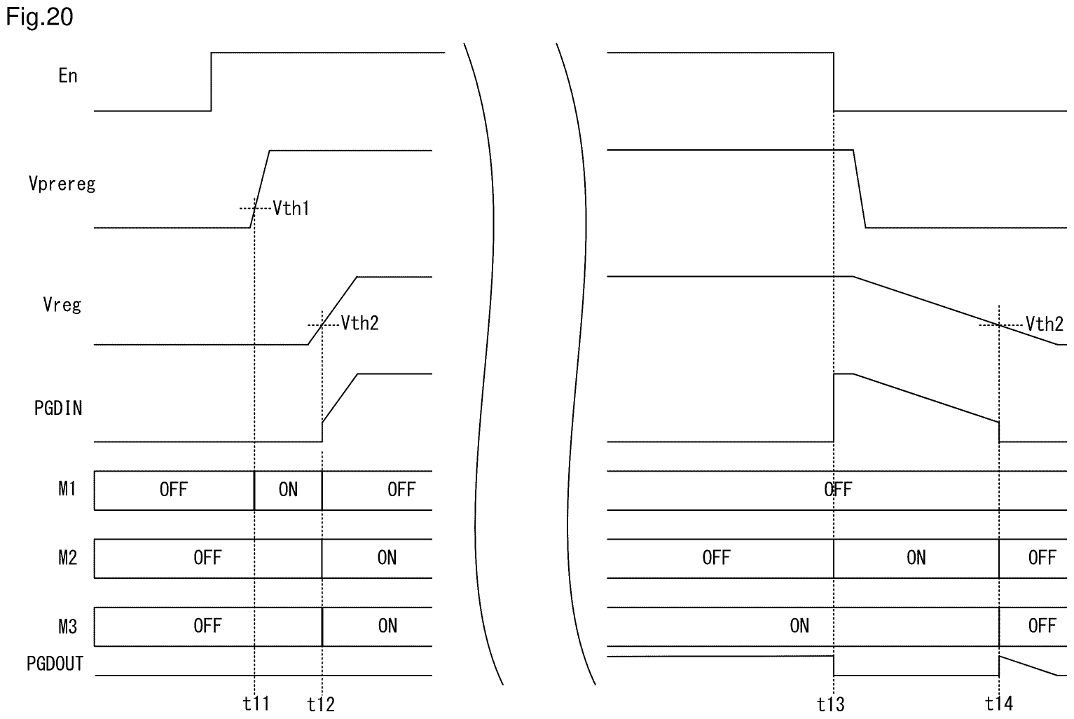

FIG. 20 is a timing chart showing operations of a power good circuit 5 according to the second embodiment when the power supply IC is started up and when the power supply IC is shut down. FIG. 20 shows, sequentially from the uppermost stage, an enable signal En, a first power supply voltage Vprereg, the second power supply voltage Vreg, a control input signal PGDIN, the on-state and the off-state of the output transistors M1, M2 and the control transistor M3 and a flag signal PGDOUT.

When the power supply IC is started up, and the first power supply voltage Vprereg reaches a threshold voltage Vth1 (timing t11), the first power supply voltage Vprereg is applied via a pull-up resistor R1 to the gate of the output transistor M1, and thus the output transistor M1 is switched from the off-state to the on-state. Here, both an output transistor M2 and the control transistor M3 are in the off-state.

Thereafter, when the second power supply voltage Vreg reaches a threshold voltage Vth2 (timing t12), the output transistor M2 and the control transistor M3 are switched from the off-state to the on-state. The control transistor M3 is brought into the on-state, and thus the output transistor M1 is switched to the off-state.

Even in the present embodiment as described above, the output transistor M1 is in the on-state until the second power supply voltage Vreg reaches the threshold voltage Vth2, and thus the flag signal PGDOUT can be prevented from being raised. The output transistor M1 is switched from the on-state to the off-state, and thus thereafter, the control of the flag signal PGDOUT is performed by the output transistor M2. In other words, in the present embodiment, the output transistor M1 is pulled up to the first power supply voltage Vprereg by the pull-up resistor R1, and thus at start-up, the flag signal PGDOUT is preferentially switched low.

When the power supply IC is shut down, the enable signal En is switched from high to low (timing t13). Here, the output voltage Vout falls, and thus the control input signal PGDIN is switched from low to high. In this way, the output transistor M2 is switched from the off-state to the on-state. Hence, the flag signal PGDOUT is switched from high to low.

Thereafter, when the second power supply voltage Vreg falls to drop below the threshold voltage Vth2 (timing t14), both the output transistor M2 and the control transistor M3 are switched from the on-state to the off-state. In this way, both the output transistors M1 and M2 are brought into the off-state.

### Third Embodiment

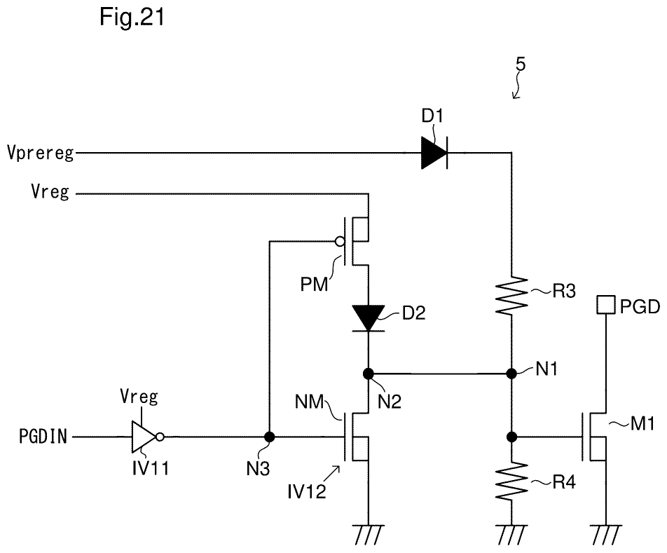

FIG. 21 is a diagram showing the configuration of a power good circuit 5 according to a third embodiment of the present disclosure. The power good circuit 5 shown in FIG. 21 includes an output transistor M1, voltage dividing resistors R3 and R4, inverters IV11 and IV12 and diodes D1 and D2. In other words, in the present embodiment, only one output transistor is provided.

The voltage dividing resistors R3 and R4 are connected in series between the application end of a first power supply voltage Vprereg and the application end of a ground potential. A node N1 to which the voltage dividing resistors R3 and R4 are connected is connected to the gate of the output transistor M1.

The input end of the inverter IV11 is connected to the application end of a control input signal PGDIN. The output end of the inverter IV11 is connected to the input end of the inverter IV12.

The inverter IV11 uses a second power supply voltage Vreg as a power supply voltage, and has the same configuration as the inverter IV1 described previously. The inverter IV12 includes a PMOS transistor PM and an NMOS transistor NM. The source of the PMOS transistor PM is connected to the application end of the second power supply voltage Vreg. The drain of the PMOS transistor PM is connected to the drain of the NMOS transistor NM. The source of the NMOS transistor NM is connected to the application end of the ground potential.

A node N3 where the gate of the PMOS transistor PM and the gate of the NMOS transistor NM are connected serves as an input end. A node N2 where the drain of the PMOS transistor PM and the drain of the NMOS transistor NM are connected serves as an output end, and the output end is connected to the node N1.

The anode of the diode D1 is connected to the application end of the first power supply voltage Vprereg. The cathode of the diode D1 is connected to one end of the voltage dividing resistor R3. The anode of the diode D2 is connected to the drain of the PMOS transistor PM. The cathode of the diode D2 is connected to the node N2.

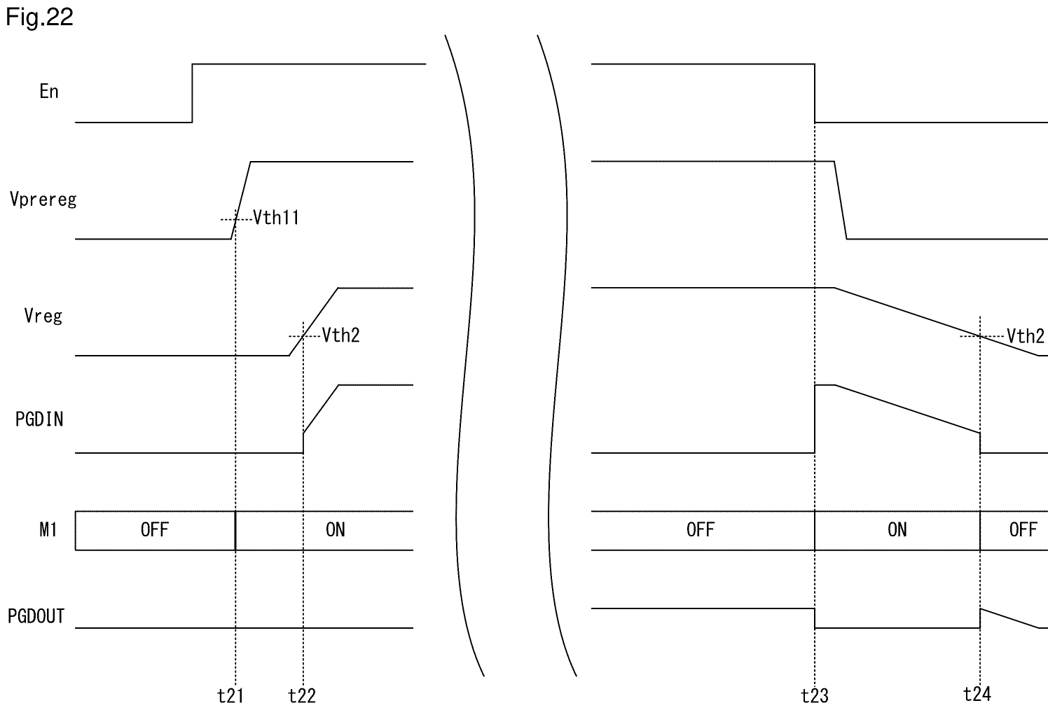

FIG. 22 is a timing chart showing operations of the power good circuit 5 according to the third embodiment when the power supply IC is started up and when the power supply IC is shut down. FIG. 22 shows, sequentially from the uppermost stage, an enable signal En, the first power supply voltage Vprereg, the second power supply voltage Vreg, the control input signal PGDIN, the on-state and the off-state of the output transistor M1 and a flag signal PGDOUT.

When the enable signal En is switched from low to high, the first power supply voltage Vprereg starts to rise to reach a threshold voltage Vth11 (timing t21). Here, a voltage obtained by dividing the first power supply voltage Vprereg with the voltage dividing resistors R3 and R4 is applied to the gate of the output transistor M1. The resistance value of the voltage dividing resistor R4 is higher than that of the voltage dividing resistor R3 (for example, R3=1 MΩ, and R4=5 MΩ). In this way, the output transistor M1 is switched from the on-state to the off-state. Here, the control input signal PGDIN is low, and thus the outputs of the inverters IV11 and IV12 are in an indeterminate logic state.

Thereafter, when the second power supply voltage Vreg reaches a threshold voltage Vth2 (timing t22), the control input signal PGDIN is switched high, and thus the output of the inverter IV12 is determined to be high. The threshold voltage Vth2 is a threshold voltage both for the output transistor M1 and for the inverters IV11 and IV12.

When the first power supply voltage Vprereg rises, it is possible to block, with the diode D2, a path which extends from the node N1 via the PMOS transistor PM to the application end of the second power supply voltage Vreg which is the level of the ground potential.

When the power supply IC is shut down, the enable signal En is switched from high to low (timing t23). Here, the output voltage Vout falls, and thus the control input signal PGDIN is switched from low to high. In this way, the output transistor M1 is switched from the off-state to the on-state. Hence, the flag signal PGDOUT is switched from high to low.

Thereafter, the first power supply voltage Vprereg falls to the ground potential. Even when the first power supply voltage Vprereg is the ground potential, the output of the inverter IV12 is high, and thus the output transistor M1 is kept in the on-state. Here, it is possible to block, with the diode D1, a path which extends from the node N1 via the voltage dividing resistor R3 to the application end of the first power supply voltage Vprereg which is the level of the ground potential.

Then, when the second power supply voltage Vreg drops below the threshold voltage Vth2 (timing t24), the control input signal PGDIN is switched low, and thus the output of the inverter IV2 is brought into an indeterminate logic state, with the result that the output transistor M1 is switched from the on-state to the off-state.

### Others

In addition to the embodiments described above, various technical features disclosed in the present specification can be variously changed without departing from the spirit of its technical creation. In other words, the embodiments described above should be considered to be illustrative in all respects and not restrictive, and it should be understood that the technical scope of the present invention is not limited to the embodiments described above, and meaning equivalent to the scope of claims and all changes belonging to the scope are included therein.

### Additional Description

As described above, a power good circuit (5) according to an aspect of the present disclosure includes: a first output transistor (M1) configured to include a first end connected to a power good terminal (PGD) and a second end connected to an application end of a ground potential; a resistor (R1) configured to apply a voltage based on a first power supply voltage (Vprereg) to a control end of the first output transistor; a first inverter stage (IV1, IV2) configured to use a second power supply voltage (Vreg) as a power supply voltage to input a control input signal (PGDIN); and a second output transistor (M2) configured to include a control end connected to an output end of the first inverter stage, a first end connected to the power good end and a second end connected to the application end of the ground potential, and the power good terminal is capable of being pulled up to the second power supply voltage (first configuration).

In the first configuration, the resistor may be a voltage dividing resistor (R3, R4) connected in series between an application end of the first power supply voltage (Vprereg) and the application end of the ground potential, and a connection node (N1) of the voltage dividing resistor may be connected to the control end of the first output transistor (M1) (second configuration).

In the second configuration, the first output transistor (M1) and the second output transistor (M1) may be the same transistor, and the power good circuit may further include a first diode (D1) configured to block a path extending from the connection node (N1) via the voltage dividing resistor (R3) to the application end of the first power supply voltage (Vprereg) and a second diode (D2) configured to block a path extending from the connection node via the first inverter stage (IV12) to an application end of the second power supply voltage (Vreg) (third configuration).

In the first configuration, the resistor may be a first pull-up resistor (R1) connected between an application end of the first power supply voltage (Vprereg) and the control end of the first output transistor (M1) (fourth configuration).

In the fourth configuration, the first output transistor (M1) and the second output transistor (M2) may be separate transistors (fifth configuration).

In the fifth configuration, the power good circuit may further include: a second pull-up resistor (R2) connected between a control end of the second output transistor (M2) and an application end of the second power supply voltage (Vreg) (sixth configuration).

In the fifth or sixth configuration, the power good circuit may further include: a level-shift circuit (51) configured to level shift the control input signal (PGDIN) from the second power supply voltage (Vreg) to the first power supply voltage (Vprereg); and a second inverter stage (IV3, IV4) provided between an output end of the level-shift circuit and the control end of the first output transistor (M1) to use the first power supply voltage as the power supply voltage (seventh configuration).

In the fifth configuration, the power good circuit may further include: a control transistor (M3) configured to include a first end connected to the control end of the first output transistor (M1), a second end connected to the application end of the ground potential and a control end connected to the application end of the second power supply voltage (Vreg) (eighth configuration).

A semiconductor device (1) according to an aspect of the present disclosure includes: the power good circuit (5) of any one of the first to eighth configurations; a pre-regulator (2) configured to input an enable signal (En) to generate the first power supply voltage (Vprereg); a reference voltage generation unit (3) configured to generate a reference voltage (Vref) based on the first power supply voltage; and a regulator (4) configured to be started up based on the reference voltage to generate the second power supply voltage (Vreg) (ninth configuration).

### <<Third Disclosed Technique>>

### <Switching Power Supply Device>

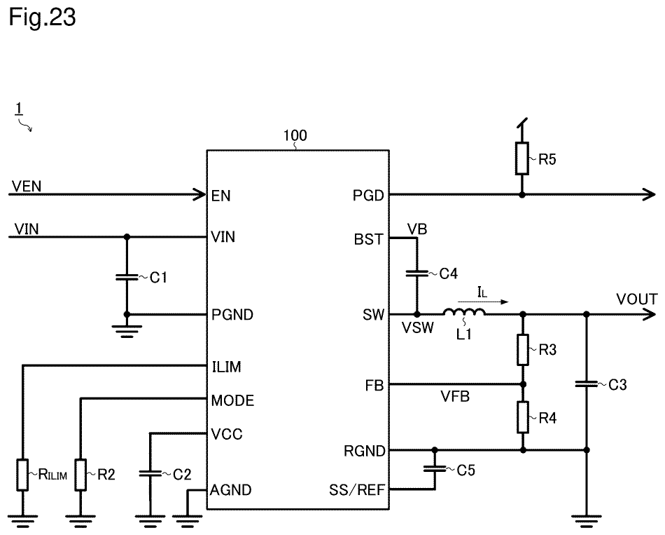

FIG. 23 is a diagram showing an overall configuration of a switching power supply device. The switching power supply device 1 in the present configuration example is a step-down DC/DC converter of a synchronous rectification system which generates a desired output voltage VOUT (for example, 0.6 to 5.5 V) from an input voltage VIN (for example, 4 to 16 V), and includes a semiconductor device 100 and various discrete components (for example, capacitors C1 to C5, an inductor L1, a resistor R_{ILIM} and resistors R2 to R5) which are externally attached to the semiconductor device 100.

The switching power supply device 1 can be preferably utilized, for example, as a step-down power supply for an SoC (system-on-a-chip), an FPGA (field-programmable gate array) or a microprocessor or as a step-down power supply for a server or a base station.

The semiconductor device 100 is a monolithic semiconductor integrated circuit device (so-called power supply control IC) which comprehensively controls the switching power supply device 1. The semiconductor device 100 includes a plurality of external terminals (in the figure, a BST terminal, an AGND terminal, an ILIM terminal, a MODE terminal, an SS/REF terminal, a RGND terminal, an FB terminal, a PGD terminal, a VIN terminal, a PGND terminal and a VCC terminal) as means for establishing electrical connection with the outside of the device.

The BST terminal is a bootstrap terminal. A bootstrap capacitor C4 (for example, 0.1 μF) is externally attached between the BST terminal and a SW terminal. A boost voltage VB (≈VSW+VCC) appearing at the BST terminal serves as a gate drive voltage for an upper transistor (not shown in the figure) incorporated in the semiconductor device 100.

The AGND terminal is a ground terminal for a control circuit (analog circuit).

The ILIM terminal is an overcurrent detection value setting terminal. An overcurrent detection value IOCP can be arbitrarily set using the resistor R_{ILIM} which is externally attached between the ILIM terminal and a ground end (=AGND terminal).

The MODE terminal is a switching control mode setting terminal. For example, the MODE terminal is pulled up or the resistor R2 which is externally attached between the MODE terminal and the ground end (=AGND) is adjusted, and thus combinations between switching frequencies (for example, 600 kHz, 800 kHz and 1 MHz), operation modes (a light load mode and a fixed PWM (pulse width modulation) mode) can be arbitrarily switched.

The SS/REF terminal is a soft start time setting terminal/internal reference voltage setting terminal. For example, a soft start time tSS for the output voltage VOUT can be arbitrarily adjusted according to the capacitance value of the capacitor C5 which is externally attached between the SS/REF terminal and the ground end (=RGND terminal). Since the output voltage VOUT gradually rises due to a soft start function, it is possible to prevent the overshoot of the output voltage VOUT and the inrush current. In the semiconductor device 100, for an output voltage tracking function, the SS/REF terminal is used to be able to externally input an internal reference voltage VREF from an external power supply. Hence, the internal reference voltage VREF can be set in any voltage range after starting up to a predetermined target value (for example, 0.6 V).

The RGND terminal is a remote sense ground terminal. When a remote sense function is omitted, a constituent element which is connected to the RGND terminal is preferably connected to the AGND terminal.

The FB terminal is an output voltage feedback terminal. The FB terminal is connected to a connection node (=the application end of a feedback voltage VFB) between the resistors R3 and R4 which are connected in series between the application end of the output voltage VOUT and the ground end (=RGND terminal). The target value of the output voltage VOUT can be set as {(R3+R4)/R4}×VREF.

The EN terminal is an enable terminal. For example, when an enable voltage VEN which is applied to the EN terminal is equal to or greater than an upper threshold value (for example, 1.22 V), the semiconductor device 100 is started up whereas when the enable voltage VEN is equal to or less than a lower threshold value (for example, 1.02 V), the semiconductor device 100 is shut down. The EN terminal needs to be terminated. The enable voltage VEN is preferably started up at the same time when the input voltage VIN is input (VIN=VEN) or after the input voltage VIN is input.

The PGD terminal is a power good terminal. Since the PGD terminal has an open-drain output system, the PGD terminal needs the pull-up resistor R5. When the PGD terminal is not used, the PGD terminal is preferably brought into a floating state or connected to the ground.

The VIN terminal is a power supply input terminal. The input smoothing capacitor C1 (for example, a ceramic capacitor of about 0.1 μF) is externally attached between the VIN terminal and the ground end (=PGND terminal). The capacitor C1 has the effect of reducing input ripple noise, the capacitor C1 is arranged as close as possible to the VIN terminal and the PGND terminal and thus the effect is achieved.

The SW terminal is a switching output terminal. The SW terminal is connected to the source of the upper transistor and the drain of a lower transistor (both of which are not shown in the figure) which are incorporated in the semiconductor device 100, and outputs a rectangular switch voltage VSW. The inductor L1 is externally attached between the SW terminal and the application end of the output voltage VOUT. The capacitor C3 (for example, a ceramic capacitor) is externally attached between the application end of the output voltage VOUT and the RGND terminal. As described above, in the switching power supply device 1, an output smoothing LC filter is needed in order to supply a continuous current to a load.

The PGND terminal is a ground terminal for a switching output stage (=power circuit).

The VCC terminal is an internal power supply output terminal. An internal power supply voltage VCC (for example, 3 V) which is output from the VCC terminal is supplied to, for example, a control circuit (=analog circuit) in the semiconductor device 100. The capacitor C2 (for example, a ceramic capacitor of about 1 μF) is externally attached between the VCC terminal and the ground end (=AGND terminal).

### <Semiconductor Device>

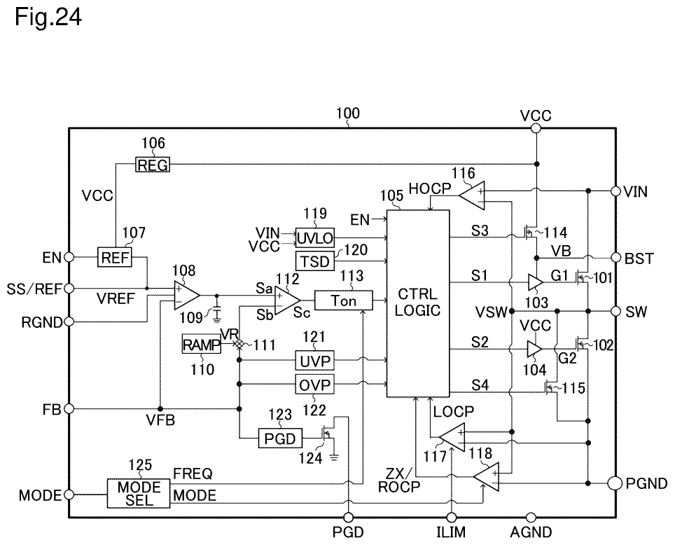

FIG. 24 is a diagram showing an internal configuration of the semiconductor device 100. The semiconductor device 100 in the present configuration example includes an upper transistor 101, a lower transistor 102, an upper driver 103, a lower driver 104, a control logic 105, an internal power supply voltage generation circuit 106, an internal reference voltage generation circuit 107, an error amplifier 108, a capacitor 109, a ramp voltage generation circuit 110, a voltage superimposition circuit 111, a main comparator 112, an on-time setting circuit 113, a P-channel MOS field effect transistor 114, an N-channel MOS field effect transistor 115, comparators 116, 117 and 118, a low input voltage malfunction prevention circuit 119, a temperature protection circuit 120, a low voltage protection circuit 121, an overvoltage protection circuit 122, a power good circuit 123, an N-channel MOS field effect transistor 124 and a mode selector 125.

The drain of the upper transistor 101 (for example, an N-channel MOS field effect transistor) is connected to the VIN terminal. The source of the upper transistor 101 is connected to the SW terminal. The gate of the upper transistor 101 is connected to the application end of an upper gate signal G1 (=the output end of the upper driver 103). The upper transistor 101 is turned on when the upper gate signal G1 is high (≈VB) whereas the upper transistor 101 is turned off when the upper gate signal G1 is low (≈VSW).

The drain of the lower transistor 102 (for example, an N-channel MOS field effect transistor) is connected to the SW terminal. The source of the lower transistor 102 is connected to the PGND terminal. The gate of the lower transistor 102 is connected to the application end of a lower gate signal G2 (=the output end of the lower driver 104). The lower transistor 102 is turned on when the lower gate signal G2 is high (≈VCC) whereas the lower transistor 102 is turned off when the lower gate signal G2 is low (≈PGND).

The upper transistor 101 and the lower transistor 102 connected as described above form, together with discrete components (the inductor L1 and the capacitor C3) externally attached to the semiconductor device 100, a step-down switching output stage which adopts the synchronous rectification system. However, the rectification system is not necessarily limited to the synchronous rectification system, and a rectifier diode may be used instead of the lower transistor 102.

When a large current output (for example, a maximum output of 20 A) is required for the switching power supply device 1, it is preferable to use elements having a low on-resistance as the upper transistor 101 and the lower transistor 102.

The upper transistor 101 and the lower transistor 102 do not necessarily need to be incorporated in the semiconductor device 100, and may be externally attached to the semiconductor device 100 as discrete components.

The upper driver 103 is operated by receiving the supply of a boot voltage VB and the switch voltage VSW, and generates the upper gate signal G1 based on an upper control signal S1 output from the control logic 105. For example, the upper driver 103 switches the upper gate signal G1 high (≈VB) when the upper control signal S1 is high whereas the upper driver 103 switches the upper gate signal G1 low (≈VSW) when the upper control signal S1 is low.

The lower driver 104 is operated by receiving the supply of the internal power supply voltage VCC and a ground voltage PGND, and generates the lower gate signal G2 based on a lower control signal S2 output from the control logic 105. For example, the lower driver 104 switches the lower gate signal G2 high (≈VCC) when the lower control signal S2 is high whereas the lower driver 104 switches the lower gate signal G2 low (≈PGND) when the lower control signal S2 is low.

When the enable signal (=the enable voltage VEN) which is input to the EN terminal is high, the control logic 105 uses a fixed on-time control system to complementarily turn on and off the upper transistor 101 and a lower transistor N2.

More specifically, the control logic 105 switches the upper control signal S1 high and switches the lower control signal S2 low when turning on the upper transistor 101 and turning off the lower transistor N2. The control logic 105 switches the upper control signal S1 low and switches the lower control signal S2 high when turning off the upper transistor 101 and turning on the lower transistor 102.

When as described above, the upper transistor 101 and the lower transistor 102 which form the switching output stage are complementarily turned on and off, the switch voltage VSW having a rectangular waveform (high level: VB, low level: PGND) is generated at the SW terminal. The switching power supply device 1 rectifies and smoothes the switch voltage VSW with an LC filter (=the inductor L1 and the capacitor C3), and thereby can generate the desired output voltage VOUT.

In order to prevent an excessive shoot-through current, the control logic 105 also has the function of preventing the upper transistor 101 and the lower transistor 102 from being turned on simultaneously. Furthermore, the control logic 105 also has the function of forcibly stopping the on/off driving of the upper transistor 101 and the lower transistor 102 based on various types of protection signals (HOCP, LOCP, ZX/ROCP, UVLO, TSD, SCP and OVP). For example, when an abnormality is detected, the control logic 105 switches both the upper control signal S1 and the lower control signal S2 low to turn off both the upper transistor 101 and the lower transistor 102.

The internal power supply voltage generation circuit 106 generates the internal power supply voltage VCC (for example, 3 V), and outputs it to the VCC terminal and the parts of the semiconductor device 100.

When the enable signal (=the enable voltage VEN) which is input to the EN terminal is high, the internal reference voltage generation circuit 107 generates a predetermined internal reference voltage VREF from the internal power supply voltage VCC and outputs it to the SS/REF terminal.

The error amplifier 108 is operated using the RGND terminal as a reference potential to generate an error signal Sa corresponding to a difference between the internal reference voltage VREF input to a non-inverting input terminal (+) and the feedback voltage VFB input to an inverting input terminal (−). Hence, the error signal Sa is increased when VREF>VFB, and is lowered when VREF<VFB.

The capacitor 109 is provided between the output end of the error amplifier 108 and the ground end (=RGND terminal). The capacitor 109 is an example of a phase compensation circuit, and prevents the oscillation of the error amplifier 108.

The ramp voltage generation circuit 110 generates a ramp voltage VR of a sawtooth or triangular waveform.

The voltage superimposition circuit 111 superimposes the ramp voltage VR on the feedback voltage VFB to generate a slope signal Sb.

The main comparator 112 compares the error signal Sa input to the non-inverting input terminal (+) with the slope signal Sb input to the inverting input terminal (−), and thereby generates a comparison signal Sc and outputs it to the on-time setting circuit 113. When Sa>Sb, the comparison signal Sc is high whereas when Sa<Sb, the comparison signal Sc is low. In other words, the main comparator 112 causes the comparison signal Sc to rise high, and thereby feeds back, to the on-time setting circuit 113, information indicating that the output voltage VOUT has been lowered beyond a target value.

When the comparison signal Sc rises high, the on-time setting circuit 113 sets a predetermined on-time Ton. The control logic 105 keeps the upper transistor 101 on and keeps the lower transistor N2 off until the on-time Ton elapses.

As described above, among the constituent elements described above, the error amplifier 108, the main comparator 112 and the on-time setting circuit 113 form an output feedback control circuit which uses the fixed on-time control system to perform drive control on the switching output stage such that the feedback voltage VFB matches the internal reference voltage VREF.

However, the output feedback control system is not necessarily limited to the fixed on-time control system, and a voltage mode control system, a current mode control system, a hysteresis control system (ripple control system) or the like may be adopted.

The drain of the transistor 114 is connected to the VCC terminal (=the application end of the internal power supply voltage VCC). The source of the transistor 114 is connected to the BST terminal (=the application end of the boot voltage VB). The transistor 114 connected as described above forms a bootstrap circuit together with the capacitor C4 which is externally attached between the BST terminal and the SW terminal.

The transistor 114 is on when a control signal S3 (=a binary signal having basically the same logic level as the control signal S1) input from the control logic 105 to the gate thereof is low whereas the transistor 114 is off when the control signal S3 is high.

The bootstrap circuit described above generates the boot voltage VB (≈VSW+VCC) which is constantly higher than the switch voltage VSW by a voltage (≈VCC) across the capacitor C4. In other words, for the boot voltage VB, VB≈VIN+VCC is satisfied during the high-level period (VSW≈VIN) of the switch voltage VSW whereas VB≈VCC is satisfied during the low-level period (VSW≈PGND) of the switch voltage VSW.

The boot voltage VB generated as described above is supplied to the upper driver 103, and is used as the high level of the upper gate signal G1 (=gate voltage for turning on the upper transistor 101). Hence, during the on-period of the upper transistor 101, the high level (≈VB) of the upper gate signal G1 is raised to a voltage value (≈VIN+VCC) which is higher than the high level (≈VIN) of the switch voltage VSW, and thus it is possible to reliably turn on the upper transistor 101 by increasing the gate-source voltage of the upper transistor 101.

As the constituent element of the bootstrap circuit, instead of the transistor 114, a diode the anode of which is connected to the VCC terminal and the cathode of which is connected to the BST terminal may be used. In this case, for the boot voltage VB, VB≈VSW+VCC−Vf is satisfied (where Vf represents the forward drop voltage of the diode).

The drain of the transistor 115 is connected to the SW terminal (=the application end of the switch voltage VSW). The source of the transistor 115 is connected to the PGND terminal (=the ground end of a power circuit). The transistor 114 is on when a control signal S4 which is input to the gate of the control logic 105 is high whereas the transistor 114 is off when the control signal S4 is low.

The transistor 115 connected as described above functions as a resistance load (for example, 80 (2) for discharging the output smoothing capacitor C3 when the semiconductor device 100 is shut down from an operation state by enable control. In other words, when the semiconductor device 100 is shut down, and thus when both the upper transistor 101 and the lower transistor 102 are turned off, the transistor 115 is preferably turned on. The output voltage VOUT may be discharged to 100% of a target value.

The comparator 116 monitors a voltage across the upper transistor 101 (=VIN−VSW) for each cycle of a switching period, and generates an upper overcurrent detection signal HOCP. When a current flowing through the upper transistor 101 reaches an overcurrent detection value IOCPH while the upper transistor 101 is on, the upper overcurrent detection signal HOCP is switched high. Here, the control logic 105 turns off the upper transistor 101 and turns on the lower transistor 102.

The comparator 117 monitors a voltage across the lower transistor 102 (=VSW) for each cycle of the switching period, and generates a lower overcurrent detection signal LOCP. In other words, the comparator 117 is a lower overcurrent detection circuit. When a current flowing through the lower transistor 102 reaches an overcurrent detection value IOCPL while the lower transistor 102 is on, the lower overcurrent detection signal LOCP is switched high. Here, even when a feedback voltage FB drops below the internal reference voltage VREF, the control logic 105 turns off the upper transistor 101 to keep a state where the lower transistor 102 is on. Thereafter, the current flowing through the lower transistor 102 drops below an upper limit value, the upper transistor 101 can be turned on.

The comparator 118 monitors a voltage across the lower transistor 102 (=VSW) for each cycle of the switching period, and generates a zero cross/sink (reverse) overcurrent detection signal ZX/ROCP. For example, in the light load mode, the control logic 105 detects zero cross timing for the current flowing through the lower transistor 102 when the lower transistor 102 is on, and turns off the lower transistor 102. In the fixed PWM mode, when the lower transistor 102 is on, the control logic 105 detects that a sink current (reverse current) flowing from the SW terminal toward the lower transistor 102 has reached an upper limit value, and the control logic 105 turns off the lower transistor 102 and turns on the upper transistor 101.

The low input voltage malfunction prevention circuit 119 monitors the input voltage VIN and the internal power supply voltage VCC, and applies UVLO (under voltage lock out) protection. For example, when the input voltage VIN is equal to or less than 1.85 V or the internal power supply voltage VCC is equal to or less than 2.5 V, the semiconductor device 100 is shut down. On the other hand, when the input voltage VIN is equal to or greater than 2.4 V and the internal power supply voltage VCC is equal to or greater than 2.8 V, the semiconductor device 100 is started up.

The temperature protection circuit 120 monitors the junction temperature Tj of the semiconductor device 100, and applies temperature protection. For example, when the junction temperature Tj is equal to or greater than 175° C., the semiconductor device 100 is shut down. Thereafter, when the junction temperature Tj is equal to or less than 150° C. (hysteresis of 25° C.), the semiconductor device 100 is automatically restarted.

The low voltage protection circuit 121 monitors the feedback voltage VFB, and applies low voltage protection. For example, when after the semiconductor device 100 is started up, the feedback voltage VFB is equal to or less than 80% of the internal reference voltage VREF, the semiconductor device 100 is shut down. When a time period of 117 ms elapses after the shutting down, the semiconductor device 100 is automatically restarted.

The overvoltage protection circuit 122 monitors the feedback voltage VFB, and applies overvoltage protection. For example, when the feedback voltage VFB is equal to or greater than 116% of the internal reference voltage VREF, the lower transistor 102 is turned on, and thus a rise in the output voltage VOUT is suppressed. Thereafter, when the feedback voltage VFB is equal to or less than 105% of the internal reference voltage VREF, the state is returned to a normal operation state.

The power good circuit 123 monitors the feedback voltage VFB, and performs on/off control on the transistor 124 (hence, output control on a power good signal PGD). For example, when the output voltage VOUT reaches a target value of 92.5% to 105%, and its state continues over a time period of 0.9 ms, the transistor 124 is turned off. On the other hand, when the output voltage VOUT is equal to or greater than 116% or equal to or less than 80%, the transistor 124 is turned on.

The drain of the transistor 124 is connected to the PGD terminal. The source of the transistor 124 is connected to the ground end (=AGND terminal). As described above, the transistor 124 is turned on and off by the power good circuit 123. When the transistor 124 is off, the PGD terminal is in a high impedance state. On the other hand, when the transistor 124 is on, the PGD terminal is pulled down to the ground end. The power good function as described above is included, and thus it is possible to perform sequence control on the overall system.

The mode selector 125 sets a switching frequency FREQ and an operation mode MODE according to the state of the MODE terminal. When the light load mode is selected as the operation mode, in a heavy load state, the switching operation is performed by PWM mode control, and in a light load state, the switching operation is performed by LLM (light load mode) mode control. On the other hand, when the fixed PWM mode is selected as the operation mode, the switching operation is forcibly performed by the PWM mode control regardless of the weight of a load. Since the efficiency of a light load region is improved in the light load mode, this function is suitable for a device which needs to reduce standby power consumption.

### <Lower Overcurrent Detection Circuit (Comparative Example)>

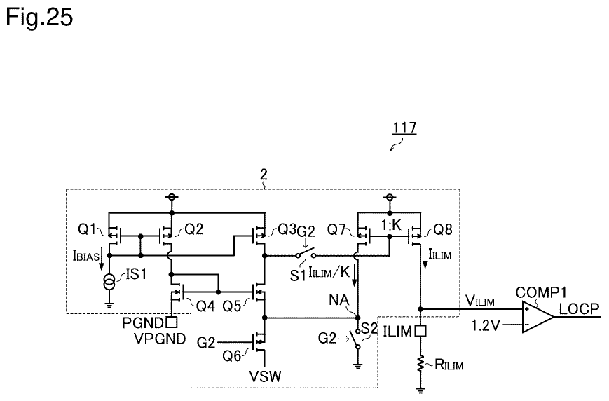

FIG. 25 is a diagram showing a comparative example of a lower overcurrent detection circuit 117 (=general configuration for comparison with embodiments to described later). The lower overcurrent detection circuit 117 in the present comparative example includes a current generation circuit 2 and a comparator COMP1.

The current generation circuit 2 generates a current I_{ILIM} corresponding to a current flowing through a lower transistor 102. The current I_{ILIM} is converted into a voltage V_{ILIM} by a resistor R_{ILIM}.

The comparator COMP1 compares the voltage V_{ILIM} and a threshold value (for example, 1.2 V), and generates and outputs a lower overcurrent detection signal LOCP which is the result of the comparison. The overcurrent detection value IOCPL described previously is determined by the threshold value (for example, 1.2 V) and the resistance value of the resistor R_{ILIM}.

The current generation circuit 2 includes a current source IS1, P-channel MOS field effect transistors Q1 to Q3 and Q7 and Q8, N-channel MOS field effect transistors Q4 to Q6 and switches S1 and S2.

The sources of the P-channel MOS field effect transistors Q1 to Q3 and Q7 and Q8 are connected to a power supply voltage application end. The gates of the P-channel MOS field effect transistors Q1 to Q3 and the drain of the P-channel MOS field effect transistor Q1 are connected to the first end of the current source IS1. The second end of the current source IS1 is connected to a ground end.

The drain of the P-channel MOS field effect transistor Q2 is connected to the gates of the N-channel MOS field effect transistors Q4 and Q5 and the drain of the N-channel MOS field effect transistor Q4. The source of the N-channel MOS field effect transistor Q4 is connected to a PGND terminal.

The drain of the P-channel MOS field effect transistor Q3 is connected via the switch S1 to the gates of the P-channel MOS field effect transistors Q7 and 8. The drain of the P-channel MOS field effect transistor Q3 is connected to the drain of the N-channel MOS field effect transistor Q5.

The source of the N-channel MOS field effect transistor Q5 is connected to the drain of the N-channel MOS field effect transistor Q6 and the drain of the P-channel MOS field effect transistor Q7. A lower gate signal G2 is supplied to the gate of the N-channel MOS field effect transistor Q6. A switch voltage VSW is applied to the source of the N-channel MOS field effect transistor Q6. A node NA where the drain of the N-channel MOS field effect transistor Q6 and the drain of the P-channel MOS field effect transistor Q7 are connected is connected via the switch S2 to the ground end.

The drain of the N-channel MOS field effect transistor Q8 is connected to the non-inverting input terminal (+) of the comparator COMP1 and an ILIM terminal.

The following relationship is established between the current I_{ILIM} generated by the current generation circuit 2 and a current IL which flows through an inductor L1.

When the lower transistor 102 is on, the current IL is represented by formula (1) below. R_{ONL} is the on-resistance of the lower transistor 102.

$${I}_{L} = ( PGND - VSW ) / {R}_{ONL} \qquad ( 1 )$$

When the lower transistor 102 is on, formula (2) below is established in the N-channel MOS field effect transistor Q6. R_{REF} is the on-resistance of the N-channel MOS field effect transistor Q6. A mirror ratio between the P-channel MOS field effect transistor Q7 and the P-channel MOS field effect transistor Q8 is 1:K.

$${I}_{ILIM} / K = ( PGND - VSW ) / {R}_{REF} \qquad ( 2 )$$

From formulae (1) and (2) described above, formula (3) below is established. K×R_{ONL}/R_{REF} is, for example, set to 10⁻⁵.

$${I}_{ILIM} = {I}_{L} \times K \times {R}_{ONL} / {R}_{REF} \qquad ( 3 )$$

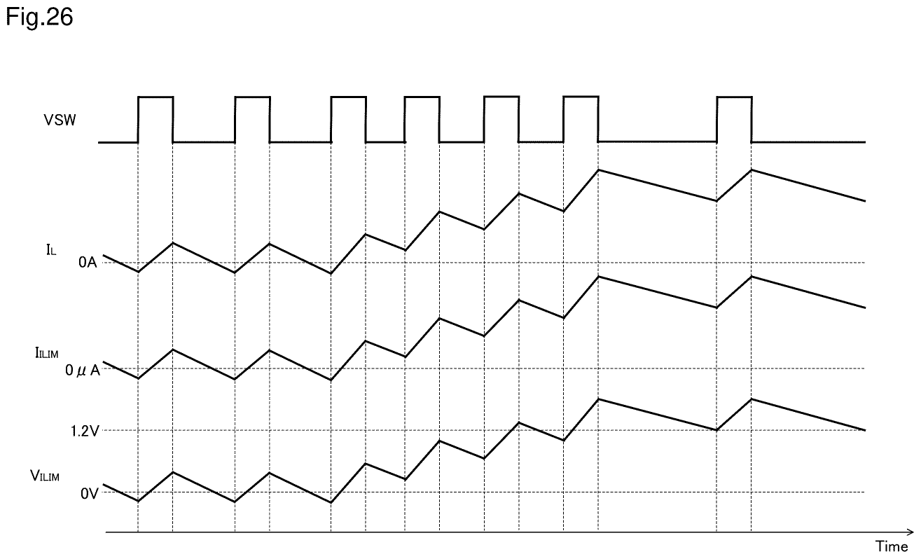

FIG. 26 is a timing chart showing ideal waveforms of voltages and currents at parts of a switching power supply device 1. The current IL is multiplied by K×R_{ONL}/R_{REF} and converted into the current I_{ILIM}. Then, the current I_{ILIM} is converted into the voltage V_{ILIM} by the resistor R_{ILIM}.

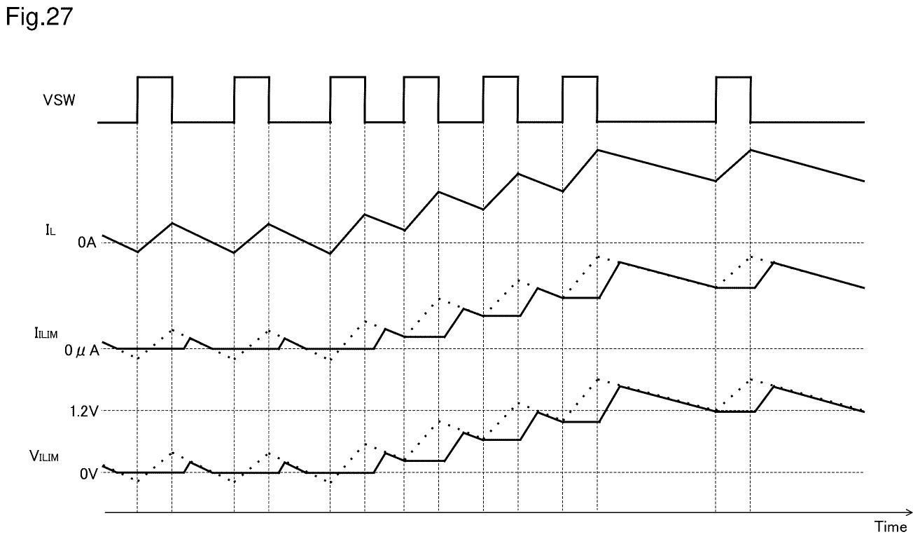

However, the current generation circuit 2 is operated when the lower transistor 102 is on. Specifically, when the lower transistor 102 is on, that is, when the lower gate signal G2 is high, the N-channel MOS field effect transistor Q6 is on, the switch S1 is on and the switch S2 is off. On the other hand, when the lower transistor 102 is off, that is, when the lower gate signal G2 is low, the N-channel MOS field effect transistor Q6 is off, the switch S1 is off and the switch S2 is on. In this way, when the lower transistor 102 is off, the gates of the P-channel MOS field effect transistors Q7 and Q8 are brought into a floating state, and its state is held, with the result that the current ILIM does not follow the current IL. Hence, the actual waveforms of voltages and currents at the parts of the switching power supply device are as indicated by solid lines in FIG. 27. In FIG. 27, the ideal waveforms are indicated by dashed lines. Even when the operation of the current generation circuit 2 is started, the current I_{ILIM} does not follow the current IL. Consequently, the detection omission of an overcurrent may occur.

In view of the considerations described above, new embodiments which can suppress the detection omission of an overcurrent will be proposed below.

### <Lower Overcurrent Detection Circuit (First Embodiment)>

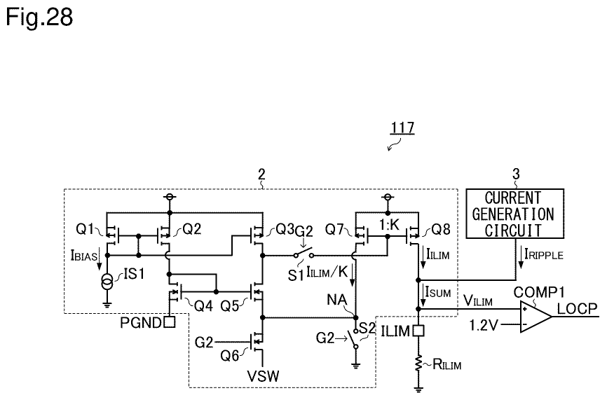

FIG. 28 is a diagram showing a first embodiment of the lower overcurrent detection circuit 117. In FIG. 28, the same parts as in FIG. 25 are identified with the same symbols, and detailed description thereof is omitted. The lower overcurrent detection circuit 117 in the present embodiment forms, together with a control logic 105, a switching control circuit which controls an upper transistor 101 and a lower transistor 102.

The lower overcurrent detection circuit 117 in the present embodiment includes current generation circuits 2 and 3 and a comparator COMP1.

The current generation circuit 3 generates a ripple current I_{RIPPLE}. The ripple current I_{RIPPLE} is greater than zero with timing at which the lower transistor 102 is switched from off to on, and varies in synchronization with the switching of the upper transistor 101 and the lower transistor 102. A current I_{SUM} obtained by adding a current I_{ILIM} and the ripple current I_{RIPPLE} is converted into a voltage V_{ILIM} by a resistor R_{ILIM}.

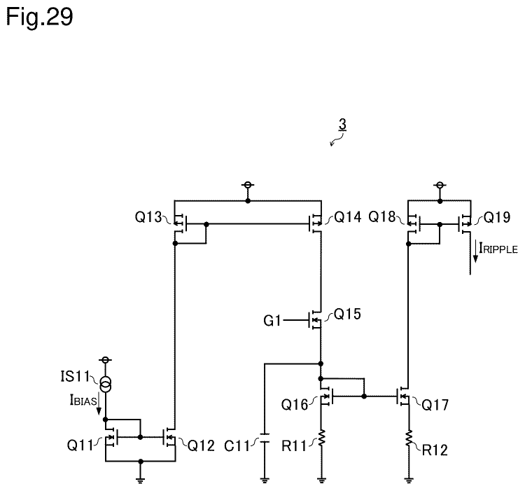

FIG. 29 is a diagram showing a first configuration example of the current generation circuit 3. The current generation circuit 3 in the first configuration example includes a current source IS11, N-channel MOS field effect transistors Q11, Q12 and Q15 to Q17, P-channel MOS field effect transistors Q13, Q14, Q18 and Q19, a capacitor C11 and resistors R11 and R12.

The first end of the current source IS11 and the sources of the P-channel MOS field effect transistors Q13, Q14, Q18 and Q19 are connected to a power supply voltage application end. The second end of the current source IS11 is connected to the gates of the N-channel MOS field effect transistors Q11 and Q12 and the drain of the N-channel MOS field effect transistor Q11.

The sources of the N-channel MOS field effect transistors Q11 and Q12 are connected to a ground end. The drain of the N-channel MOS field effect transistor Q12 is connected to the gates of the P-channel MOS field effect transistors Q13 and Q14 and the drain of the P-channel MOS field effect transistor Q13.

The drain of the P-channel MOS field effect transistor Q14 is connected to the drain of the N-channel MOS field effect transistor Q15. An upper gate signal G1 is supplied to the gate of N-channel MOS field effect transistor Q15.

The source of the N-channel MOS field effect transistor Q15 is connected to the first end of the capacitor C11, the gates of the N-channel MOS field effect transistors Q16 and Q17 and the drain of the N-channel MOS field effect transistor Q16.

The source of the N-channel MOS field effect transistor Q16 is connected via the resistor R11 to the ground end. The source of the N-channel MOS field effect transistor Q17 is connected via the resistor R12 to the ground end.

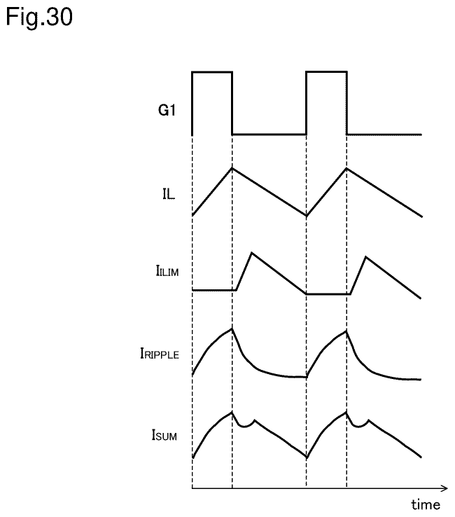

The drain of the N-channel MOS field effect transistor Q17 is connected to the gates of the P-channel MOS field effect transistors Q18 and Q19 and the drain of the P-channel MOS field effect transistor Q18. A ripple current I_{RIPPLE} is output from the drain of the P-channel MOS field effect transistor Q19. The ripple current I_{RIPPLE} is varied according to a RC time constant. As shown in FIG. 30, when the lower transistor 102 is off, the ripple current I_{RIPPLE} is increased with time whereas when the lower transistor 102 is on, the ripple current I_{RIPPLE} is decreased with time. This causes the voltage V_{ILIM} to approach an ideal waveform.

For example, when the following settings are made, the maximum value of the ripple current I_{RIPPLE} is 40 μA. A current I_{BIAS} which is output from the current source IS11 is 0.5 μA. The capacitance of the capacitor is 0.7 pF. The resistance value of the resistor R11 is 50 kΩ. The resistance value of the resistor R12 is 12.5 kΩ. A mirror ratio between the N-channel MOS field effect transistor Q11 and the N-channel MOS field effect transistor Q12 is 1:2. A mirror ratio between the P-channel MOS field effect transistor Q13 and the P-channel MOS field effect transistor Q14 is 1:2. A mirror ratio between the N-channel MOS field effect transistor Q16 and the N-channel MOS field effect transistor Q17 is 1:4. A mirror ratio between the P-channel MOS field effect transistor Q18 and the P-channel MOS field effect transistor Q19 is 1:5.

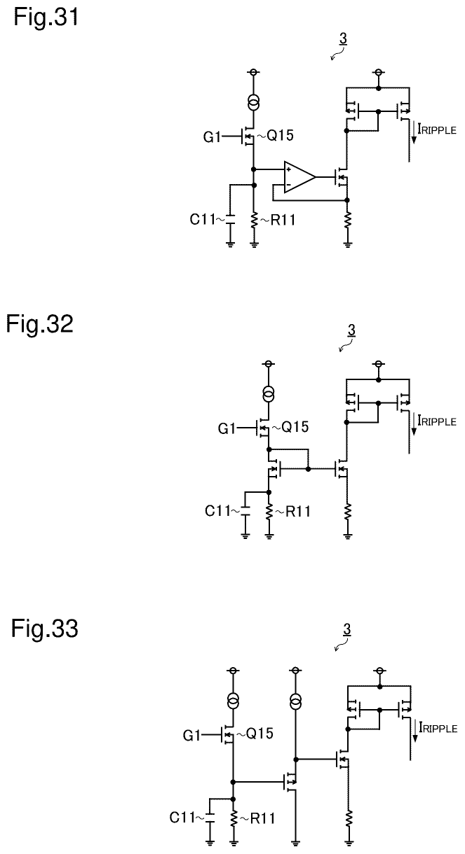

Instead of the current generation circuit 3 in the first configuration example, any one of current generation circuits 3 in second to fourth configuration examples shown in FIGS. 31 to 33 may be used. The current generation circuits 3 in the second to fourth configuration examples each include, as with the current generation circuit 3 in the first configuration example, an N-channel MOS field effect transistor Q15 in which an upper gate signal G1 is supplied to the gate thereof, a capacitor C11 and a resistor R11.

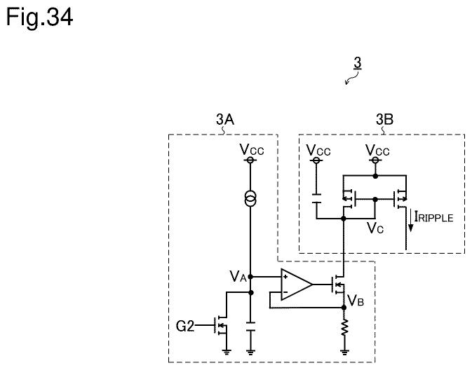

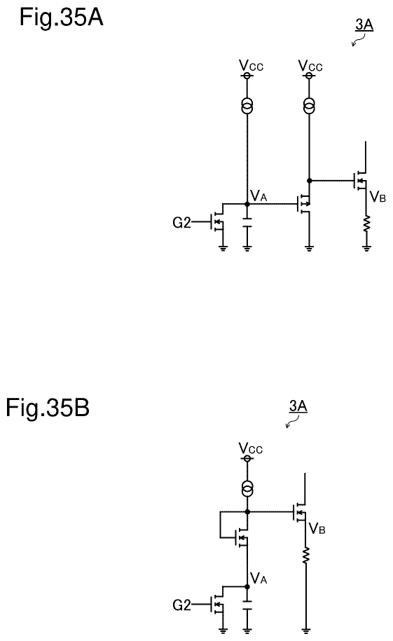

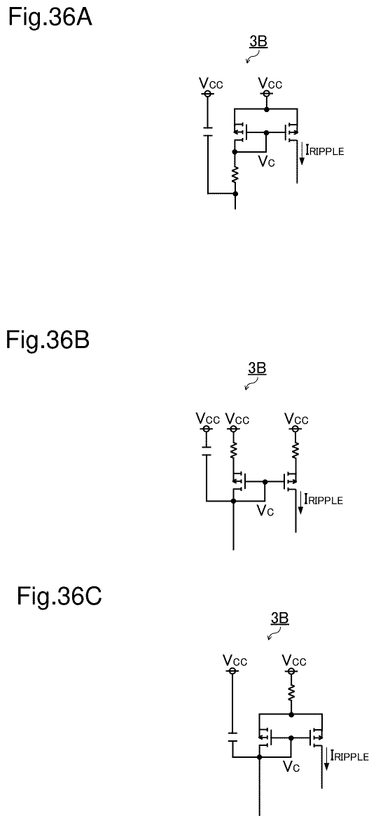

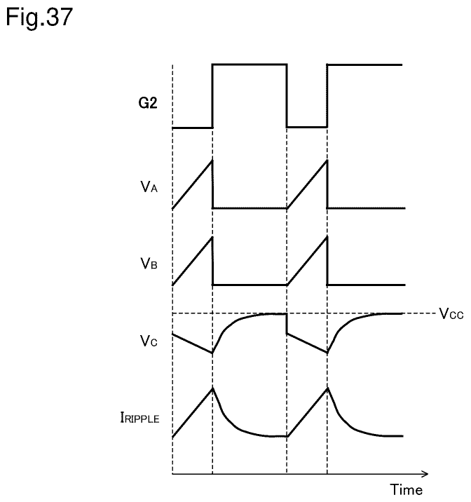

Instead of the current generation circuit 3 in the first configuration example, a current generation circuit 3 in a fifth configuration example shown in FIG. 34 may be used. A lower gate signal G2 is suppled to the current generation circuit 3 in the fifth configuration example shown in FIG. 34. The current generation circuit 3 in the fifth configuration example shown in FIG. 34 includes a first circuit 3A and a second circuit 3B. Instead of the first circuit 3A in FIG. 34, a first circuit 3A shown in FIG. 35A or a first circuit 3A shown in FIG. 35B may be used. Instead of the second circuit 3B in FIG. 34, a second circuit 3B shown in any one of FIGS. 36A to 36C may be used. FIG. 37 is a timing chart showing actual waveforms of voltages and currents at parts of a switching power supply device 1 which includes the current generation circuit 3 in the fifth configuration example shown in FIG. 34.

### <Lower Overcurrent Detection Circuit (Second Embodiment)>

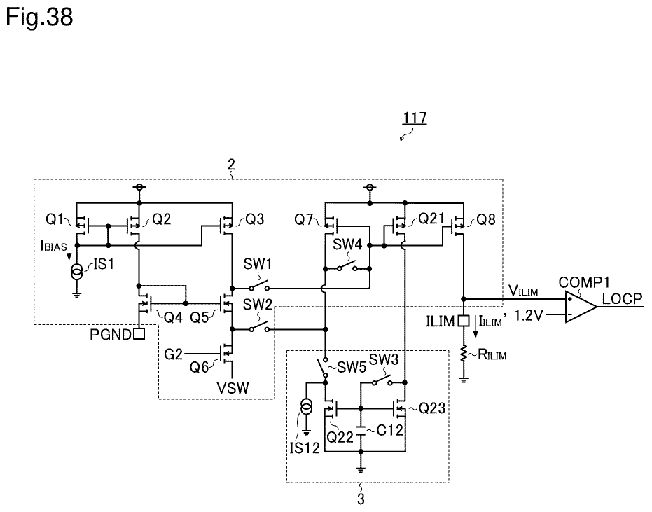

FIG. 38 is a diagram showing a second embodiment of the lower overcurrent detection circuit 117. The lower overcurrent detection circuit 117 in the present embodiment forms, together with a control logic 105, a switching control circuit which controls an upper transistor 101 and a lower transistor 102.

The lower overcurrent detection circuit 117 in the present embodiment has a configuration in which switches SW1 to SW5, a P-channel MOS field effect transistor Q21, N-channel MOS field effect transistors Q22 and Q23, a capacitor C12 and a current source IS12 are added to the lower overcurrent detection circuit 117 in the comparative example.

The switches SW1 to SW3 are off when the lower transistor 102 is off whereas the switches SW1 to SW3 are on when the lower transistor 102 is on. The switches SW4 and SW5 are on when the lower transistor 102 is off whereas the switches SW4 and SW5 are off when the lower transistor 102 is on.

The capacitor C12 holds information of a current I_{ILIM}′ immediately before the lower transistor 102 is turned off. When the lower transistor 102 is off, a current generation circuit 3 outputs a current obtained by adding the current in the information held by the capacitor C12 and a current output from the current source IS12.

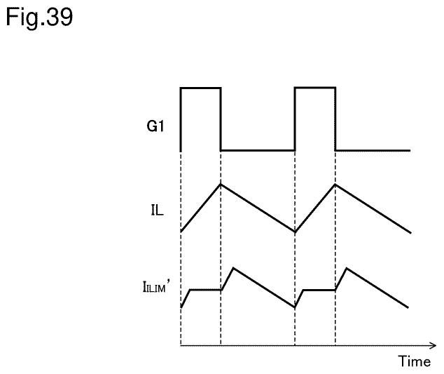

Since the lower overcurrent detection circuit 117 in the present embodiment can obtain the current I_{ILIM}′ of a waveform shown in FIG. 39, as in the lower overcurrent detection circuit 117 in the first embodiment, it is possible to suppress the detection omission of an overcurrent.

### <Lower Overcurrent Detection Circuit (Third Embodiment)>

In the lower overcurrent detection circuit 117 in the first embodiment and the lower overcurrent detection circuit 117 in the second embodiment, when there is an offset in the N-channel MOS field effect transistors Q4 and Q5 which are an input differential pair of transistors in a first current generation circuit 2, the accuracy of the current I_{ILIM} is deteriorated.

The lower overcurrent detection circuit 117 in a third embodiment is configured to cancel an offset in N-channel MOS field effect transistors Q4 and Q5 which are an input differential pair of transistors in a first current generation circuit 2. Hence, in the lower overcurrent detection circuit 117 in the third embodiment, as compared with the lower overcurrent detection circuit 117 in the first embodiment and the lower overcurrent detection circuit 117 in the second embodiment, the accuracy of the current I_{ILIM} can be enhanced.

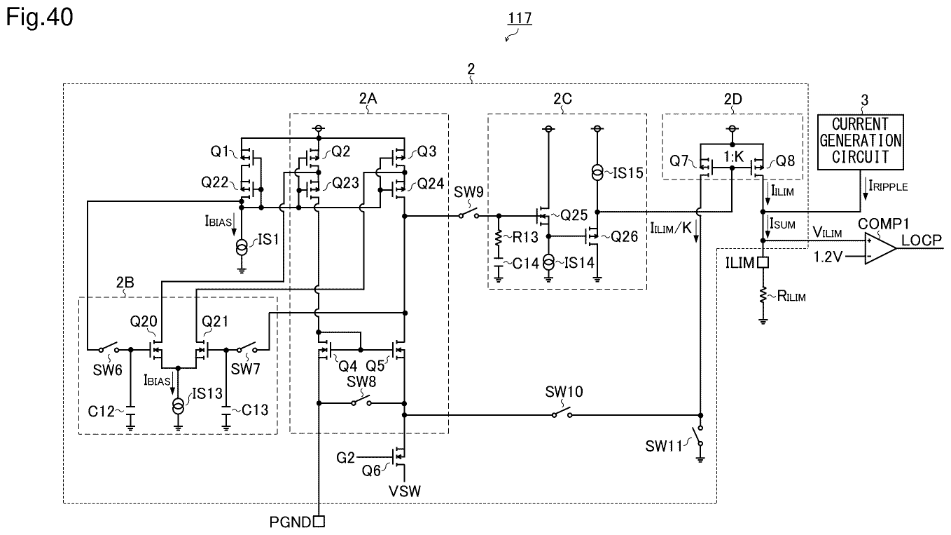

FIG. 40 is a diagram showing the third embodiment of the lower overcurrent detection circuit 117. The lower overcurrent detection circuit 117 in the present embodiment is a circuit based on the lower overcurrent detection circuit 117 in the first embodiment. In FIG. 40, the same parts as in FIG. 28 are identified with the same symbols, and detailed description thereof is omitted.

The lower overcurrent detection circuit 117 in the present embodiment includes an input differential unit 2A, an offset sampling unit 2B, a phase compensation and output drive unit 2C, an output unit 2D, P-channel MOS field effect transistors Q1 and Q22, a current source IS1, an N-channel MOS field effect transistor Q6 and switches SW9 to SW11.

The switches SW6, SW7, SW8 and SW11 and the switches SW9 and SW10 are complementarily turned on and off.

The switches SW6, SW7, SW8 and SW11 are on when the lower transistor 102 is off. Here, the source of the N-channel MOS field effect transistor Q4 and the source of the N-channel MOS field effect transistor Q5 are short-circuited by the switch SW8.

Capacitors C12 and C13 are charged such that the drain voltage of the P-channel MOS field effect transistor Q22 matches the drain voltage of the P-channel MOS field effect transistor Q24.

The switches SW9 and SW10 are on when the lower transistor 102 is on. Here, the drain currents of the N-channel MOS field effect transistors Q4 and Q5 are adjusted by the charging voltage of the capacitors C12 and C13, with the result that the offset in the N-channel MOS field effect transistors Q4 and Q5 is cancelled.

### Others

In addition to the embodiments described above, the configuration of the invention can be variously changed without departing from the spirit of the invention. The embodiments described above should be considered to be illustrative in all respects and not restrictive, and it should be understood that the technical scope of the present invention is indicated not by the description of the embodiments but by the scope of claims, and meaning equivalent to the scope of claims and all changes belonging to the scope are included therein.

### Additional Description

Although in the embodiments described above, the resistor R_{ILIM} is a component which is additionally attached to the semiconductor device 100, the resistor R_{ILIM} may be incorporated in the semiconductor device 100. Although in the embodiments and variations described above, the current generation circuit 3 which generates the ripple current I_{RIPPLE} is a circuit which is operated with reference to the ground potential, the current generation circuit 3 may be a circuit which is operated with reference to the power supply voltage.

The overcurrent detection circuit (117) described above is an overcurrent detection circuit configured such that a first switch (101) and a second switch (102) are connected in series, and the second switch is provided on a lower potential side than the first switch, and configured to detect an overcurrent flowing through the second switch in a circuit in which an inductor is connected to a connection node of the first switch and the second switch, and the overcurrent detection circuit includes: a first current generation circuit (2) configured to generate a first current corresponding to a current flowing through the second switch; a second current generation circuit (3) configured to generate a second current that is greater than zero with timing at which the second switch is switched from off to on and varies in synchronization with switching of the first switch and the second switch; and a comparator (COMP1) configured to compare a voltage corresponding to the first current and the second current with a threshold value (first configuration).

The overcurrent detection circuit of the first configuration can suppress the detection omission of an overcurrent.

In the overcurrent detection circuit of the first configuration, the second current generation circuit may include a third switch (Q15) configured to be on when the first switch is on and to be off when the first switch is off or a fourth switch configured to be off when the first switch is on and to be on when the first switch is off (second configuration).

The overcurrent detection circuit of the second configuration facilitates the generation of the second current.

In the overcurrent detection circuit of the first or second configuration, the second current generation circuit may include a circuit configured with a resistor (R11) and a capacitor (C11) (third configuration).

The overcurrent detection circuit of the third configuration can easily vary the second current with a RC time constant.

In the overcurrent detection circuit of any one of the first to third configurations, the second current may be increased with time when the second switch is off, and may be decreased with time when the second switch is on (fourth configuration).

The overcurrent detection circuit of the fourth configuration can cause the voltage corresponding to the first current and the second current to approach an ideal waveform.

In the overcurrent detection circuit of the first configuration, the second current generation circuit may include a third switch (SW5) configured to be on when the first switch is on and to be off when the first switch is off and a fourth switch (SW3) configured to be off when the first switch is on and to be on when the first switch is off (fifth configuration).

The overcurrent detection circuit of the fifth configuration facilitates the generation of the second current.

In the overcurrent detection circuit of the first or fifth configuration, the second current generation circuit may be configured to hold information of the first current immediately before the second switch is turned off (sixth configuration).

The overcurrent detection circuit of the sixth configuration utilizes the information of the first current immediately before the second switch is turned off, and thereby can set the second current to an appropriate value.

In the overcurrent detection circuit of the sixth configuration, the second current may have a value corresponding to the information when the second switch is off (seventh configuration).

The overcurrent detection circuit of the seventh configuration utilizes the information of the first current immediately before the second switch is turned off, and thereby can set the second current to an appropriate value.

In the overcurrent detection circuit of any one of the first to seventh configurations, the first current generation circuit may be configured to cancel an offset in an input differential pair of transistors in the first current generation circuit (eighth configuration).

The overcurrent detection circuit of the eighth configuration can enhance the accuracy of the first current.

The switching control circuit described above includes: the overcurrent detection circuit of any one of the first to eighth configurations; and a control unit (105) configured to control the first switch and the second switch (ninth configuration).

The switching control circuit of the ninth configuration can suppress the detection omission of an overcurrent.

The switching power supply device (1) described above includes: the switching control circuit of the ninth configuration; and the first switch and the second switch (tenth configuration).

The switching power supply device of the tenth configuration can suppress the detection omission of an overcurrent.

### Fourth Disclosed Technique

### <Switching Power Supply Device>

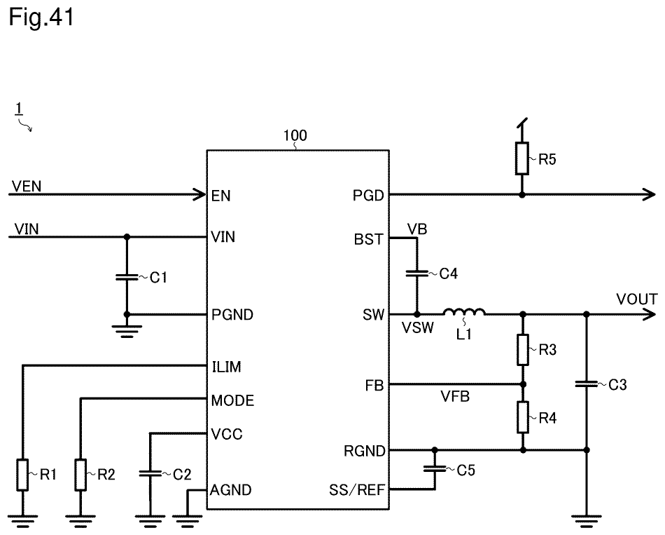

FIG. 41 is a diagram showing an overall configuration of a switching power supply device. The switching power supply device 1 in the present configuration example is a step-down DC/DC converter of the synchronous rectification system which generates a desired output voltage VOUT (for example, 0.6 to 5.5 V) from an input voltage VIN (for example, 4 to 16 V), and includes a semiconductor device 100 and various discrete components (for example, capacitors C1 to C5, an inductor L1 and resistors R1 to R5) which are externally attached to the semiconductor device 100.

The switching power supply device 1 can be preferably utilized, for example, as a step-down power supply for an SoC (system-on-a-chip), an FPGA (field-programmable gate array) or a microprocessor or as a step-down power supply for a server or a base station.

The semiconductor device 100 is a monolithic semiconductor integrated circuit device (so-called power supply control IC) which comprehensively controls the switching power supply device 1. The semiconductor device 100 includes a plurality of external terminals (in the figure, a BST terminal, an AGND terminal, an ILIM terminal, a MODE terminal, an SS/REF terminal, a RGND terminal, an FB terminal, a PGD terminal, a VIN terminal, a PGND terminal and a VCC terminal) as means for establishing electrical connection with the outside of the device.

The BST terminal is a bootstrap terminal. A bootstrap capacitor C4 (for example, 0.1 μF) is externally attached between the BST terminal and a SW terminal. A boost voltage VB (≈VSW+VCC) appearing at the BST terminal serves as a gate drive voltage for an upper transistor (not shown in the figure) incorporated in the semiconductor device 100.

The AGND terminal is a ground terminal for a control circuit (analog circuit).

The ILIM terminal is an overcurrent detection value setting terminal. An overcurrent detection value IOCP can be arbitrarily set using the resistor R1 which is externally attached between the ILIM terminal and a ground end (=AGND terminal).

The MODE terminal is a switching control mode setting terminal. For example, the MODE terminal is pulled up or the resistor R2 which is externally attached between the MODE terminal and the ground end (=AGND) is adjusted, and thus combinations between switching frequencies (for example, 600 kHz, 800 kHz and 1 MHz), operation modes (a light load mode and a fixed PWM (pulse width modulation) mode) can be arbitrarily switched.

The SS/REF terminal is a soft start time setting terminal/internal reference voltage setting terminal. For example, a soft start time tSS for the output voltage VOUT can be arbitrarily adjusted according to the capacitance value of the capacitor C5 which is externally attached between the SS/REF terminal and the ground end (=RGND terminal). Since the output voltage VOUT gradually rises due to a soft start function, it is possible to prevent the overshoot of the output voltage VOUT and the inrush current. In the semiconductor device 100, for an output voltage tracking function, the SS/REF terminal is used to be able to externally input an internal reference voltage VREF from an external power supply. Hence, the internal reference voltage VREF can be set in any voltage range after starting up to a predetermined target value (for example, 0.6 V).

The RGND terminal is a remote sense ground terminal. When a remote sense function is omitted, a constituent element which is connected to the RGND terminal is preferably connected to the AGND terminal.

The FB terminal is an output voltage feedback terminal. The FB terminal is connected to a connection node (=the application end of a feedback voltage VFB) between the resistors R3 and R4 which are connected in series between the application end of the output voltage VOUT and the ground end (=RGND terminal). The target value of the output voltage VOUT can be set as {(R3+R4)/R4}×VREF.

The EN terminal is an enable terminal. For example, when an enable voltage VEN which is applied to the EN terminal is equal to or greater than an upper threshold value (for example, 1.22 V), the semiconductor device 100 is started up whereas when the enable voltage VEN is equal to or less than a lower threshold value (for example, 1.02 V), the semiconductor device 100 is shut down. The EN terminal needs to be terminated. The enable voltage VEN is preferably started up at the same time when the input voltage VIN is input (VIN=VEN) or after the input voltage VIN is input.

The PGD terminal is a power good terminal. Since the PGD terminal has an open-drain output system, the PGD terminal needs the pull-up resistor R5. When the PGD terminal is not used, the PGD terminal is preferably brought into a floating state or connected to the ground.

The VIN terminal is a power supply input terminal. The input smoothing capacitor C1 (for example, a ceramic capacitor of about 0.1 μF) is externally attached between the VIN terminal and the ground end (=PGND terminal). The capacitor C1 has the effect of reducing input ripple noise, the capacitor C1 is arranged as close as possible to the VIN terminal and the PGND terminal and thus the effect is achieved.

The SW terminal is a switching output terminal. The SW terminal is connected to the source of the upper transistor and the drain of a lower transistor (both of which are not shown in the figure) which are incorporated in the semiconductor device 100, and outputs a rectangular switch voltage VSW. The inductor L1 is externally attached between the SW terminal and the application end of the output voltage VOUT. The capacitor C3 (for example, a ceramic capacitor) is externally attached between the application end of the output voltage VOUT and the RGND terminal. As described above, in the switching power supply device 1, an output smoothing LC filter is needed in order to supply a continuous current to a load.

The PGND terminal is a ground terminal for a switching output stage (=power circuit).

The VCC terminal is an internal power supply output terminal. An internal power supply voltage VCC (for example, 3 V) which is output from the VCC terminal is supplied to, for example, a control circuit (=analog circuit) in the semiconductor device 100. The capacitor C2 (for example, a ceramic capacitor of about 1 μF) is externally attached between the VCC terminal and the ground end (=AGND terminal).

### <Semiconductor Device>

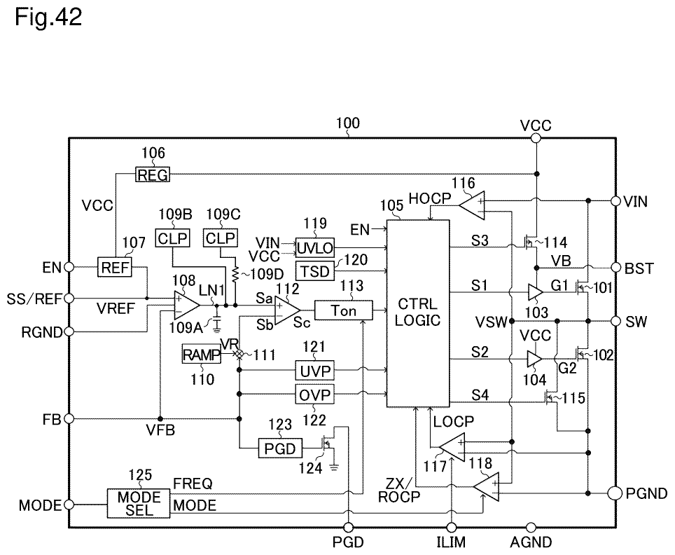

FIG. 42 is a diagram showing an internal configuration of the semiconductor device 100. The semiconductor device 100 in the present configuration example includes an upper transistor 101, a lower transistor 102, an upper driver 103, a lower driver 104, a control logic 105, an internal power supply voltage generation circuit 106, an internal reference voltage generation circuit 107, an error amplifier 108, a capacitor 109A, a lower clamp circuit 109B, an upper clamp circuit 109C, a resistor 109D, a ramp voltage generation circuit 110, a voltage superimposition circuit 111, a main comparator 112, an on-time setting circuit 113, a P-channel MOS field effect transistor 114, an N-channel MOS field effect transistor 115, comparators 116, 117 and 118, a low input voltage malfunction prevention circuit 119, a temperature protection circuit 120, a low voltage protection circuit 121, an overvoltage protection circuit 122, a power good circuit 123, an N-channel MOS field effect transistor 124 and a mode selector 125.

The drain of the upper transistor 101 (for example, an N-channel MOS field effect transistor) is connected to the VIN terminal. The source of the upper transistor 101 is connected to the SW terminal. The gate of the upper transistor 101 is connected to the application end of an upper gate signal G1 (=the output end of the upper driver 103). The upper transistor 101 is turned on when the upper gate signal G1 is high (≈VB) whereas the upper transistor 101 is turned off when the upper gate signal G1 is low (≈VSW).

The drain of the lower transistor 102 (for example, an N-channel MOS field effect transistor) is connected to the SW terminal. The source of the lower transistor 102 is connected to the PGND terminal. The gate of the lower transistor 102 is connected to the application end of a lower gate signal G2 (=the output end of the lower driver 104). The lower transistor 102 is turned on when the lower gate signal G2 is high (≈VCC) whereas the lower transistor 102 is turned off when the lower gate signal G2 is low (≈PGND).

The upper transistor 101 and the lower transistor 102 connected as described above form, together with discrete components (the inductor L and the capacitor C3) externally attached to the semiconductor device 100, a step-down switching output stage which adopts the synchronous rectification system. However, the rectification system is not necessarily limited to the synchronous rectification system, and a rectifier diode may be used instead of the lower transistor 102.

When a large current output (for example, a maximum output of 20 A) is required for the switching power supply device 1, it is preferable to use elements having a low on-resistance as the upper transistor 101 and the lower transistor 102.

The upper transistor 101 and the lower transistor 102 do not necessarily need to be incorporated in the semiconductor device 100, and may be externally attached to the semiconductor device 100 as discrete components.

The upper driver 103 is operated by receiving the supply of a boot voltage VB and the switch voltage VSW, and generates the upper gate signal G1 based on an upper control signal S1 output from the control logic 105. For example, the upper driver 103 switches the upper gate signal G1 high (≈VB) when the upper control signal S1 is high whereas the upper driver 103 switches the upper gate signal G1 low (≈VSW) when the upper control signal S1 is low.

The lower driver 104 is operated by receiving the supply of the internal power supply voltage VCC and a ground voltage PGND, and generates the lower gate signal G2 based on a lower control signal S2 output from the control logic 105. For example, the lower driver 104 switches the lower gate signal G2 high (≈VCC) when the lower control signal S2 is high whereas the lower driver 104 switches the lower gate signal G2 low (≈PGND) when the lower control signal S2 is low.

When the enable signal (=the enable voltage VEN) which is input to the EN terminal is high, the control logic 105 uses a fixed on-time control system to complementarily turn on and off the upper transistor 101 and a lower transistor N2.

More specifically, the control logic 105 switches the upper control signal S1 high and switches the lower control signal S2 low when turning on the upper transistor 101 and turning off the lower transistor N2. The control logic 105 switches the upper control signal S1 low and switches the lower control signal S2 high when turning off the upper transistor 101 and turning on the lower transistor 102.

When as described above, the upper transistor 101 and the lower transistor 102 which form the switching output stage are complementarily turned on and off, the switch voltage VSW having a rectangular waveform (high level: VB, low level: PGND) is generated at the SW terminal. The switching power supply device 1 rectifies and smoothes the switch voltage VSW with an LC filter (=the inductor L1 and the capacitor C3), and thereby can generate the desired output voltage VOUT.

In order to prevent an excessive shoot-through current, the control logic 105 also has the function of preventing the upper transistor 101 and the lower transistor 102 from being turned on simultaneously. Furthermore, the control logic 105 also has the function of forcibly stopping the on/off driving of the upper transistor 101 and the lower transistor 102 based on various types of protection signals (HOCP, LOCP, ZX/ROCP, UVLO, TSD, SCP and OVP). For example, when an abnormality is detected, the control logic 105 switches both the upper control signal S1 and the lower control signal S2 low to turn off both the upper transistor 101 and the lower transistor 102.

The internal power supply voltage generation circuit 106 generates the internal power supply voltage VCC (for example, 3 V), and outputs it to the VCC terminal and the parts of the semiconductor device 100.

When the enable signal (=the enable voltage VEN) which is input to the EN terminal is high, the internal reference voltage generation circuit 107 generates a predetermined internal reference voltage VREF from the internal power supply voltage VCC and outputs it to the SS/REF terminal.

The error amplifier 108 is operated using the RGND terminal as a reference potential to generate an error signal Sa corresponding to a difference between the internal reference voltage VREF input to a non-inverting input terminal (+) and the feedback voltage VFB input to an inverting input terminal (−). Hence, the error signal Sa is increased when VREF>VFB, and is lowered when VREF<VFB.

The capacitor 109A is provided between the output end of the error amplifier 108 and the ground end (=RGND terminal). The capacitor 109A is an example of a phase compensation circuit, and prevents the oscillation of the error amplifier 108. The lower clamp circuit 109B clamps the error signal Sa such that the error signal Sa is prevented from dropping below a first predetermined value. The upper clamp circuit 109C clamps the error signal Sa such that the error signal Sa is prevented from exceeding a second predetermined value (>the first predetermined value). The resistor 109D is provided between the signal line LN1 which transfers the error signal Sa and the upper clamp circuit 109C.

The ramp voltage generation circuit 110 generates a ramp voltage VR of a sawtooth or triangular waveform.

The voltage superimposition circuit 111 superimposes the ramp voltage VR on the feedback voltage VFB to generate a slope signal Sb.

The main comparator 112 compares the error signal Sa input to the non-inverting input terminal (+) with the slope signal Sb input to the inverting input terminal (−), and thereby generates a comparison signal Sc and outputs it to the on-time setting circuit 113. When Sa>Sb, the comparison signal Sc is high whereas when Sa<Sb, the comparison signal Sc is low. In other words, the main comparator 112 causes the comparison signal Sc to rise high, and thereby feeds back, to the on-time setting circuit 113, information indicating that the output voltage VOUT has been lowered beyond a target value.

When the comparison signal Sc rises high, the on-time setting circuit 113 sets a predetermined on-time Ton. The control logic 105 keeps the upper transistor 101 on and keeps the lower transistor N2 off until the on-time Ton elapses.

As described above, among the constituent elements described above, the error amplifier 108, the main comparator 112 and the on-time setting circuit 113 form an output feedback control circuit which uses the fixed on-time control system to perform drive control on the switching output stage such that the feedback voltage VFB matches the internal reference voltage VREF.

However, the output feedback control system is not necessarily limited to the fixed on-time control system, and a voltage mode control system, a current mode control system, a hysteresis control system (ripple control system) or the like may be adopted.

The drain of the transistor 114 is connected to the VCC terminal (=the application end of the internal power supply voltage VCC). The source of the transistor 114 is connected to the BST terminal (=the application end of the boot voltage VB). The transistor 114 connected as described above forms a bootstrap circuit together with the capacitor C4 which is externally attached between the BST terminal and the SW terminal.

The transistor 114 is on when a control signal S3 (=a binary signal having basically the same logic level as the control signal S1) input from the control logic 105 to the gate thereof is low whereas the transistor 114 is off when the control signal S3 is high.

The bootstrap circuit described above generates the boot voltage VB (≈VSW+VCC) which is constantly higher than the switch voltage VSW by a voltage (≈VCC) across the capacitor C4. In other words, for the boot voltage VB, VB≈VIN+VCC is satisfied during the high-level period (VSW≈VIN) of the switch voltage VSW whereas VB≈VCC is satisfied during the low-level period (VSW≈PGND) of the switch voltage VSW.

The boot voltage VB generated as described above is supplied to the upper driver 103, and is used as the high level of the upper gate signal G1 (=gate voltage for turning on the upper transistor 101). Hence, during the on-period of the upper transistor 101, the high level (≈VB) of the upper gate signal G1 is raised to a voltage value (≈VIN+VCC) which is higher than the high level (≈VIN) of the switch voltage VSW, and thus it is possible to reliably turn on the upper transistor 101 by increasing the gate-source voltage of the upper transistor 101.

As the constituent element of the bootstrap circuit, instead of the transistor 114, a diode the anode of which is connected to the VCC terminal and the cathode of which is connected to the BST terminal may be used. In this case, for the boot voltage VB, VB≈VSW+VCC−Vf is satisfied (where Vf represents the forward drop voltage of the diode).

The drain of the transistor 115 is connected to the SW terminal (=the application end of the switch voltage VSW). The source of the transistor 115 is connected to the PGND terminal (=the ground end of a power circuit). The transistor 114 is on when a control signal S4 which is input to the gate of the control logic 105 is high whereas the transistor 114 is off when the control signal S4 is low.

The transistor 115 connected as described above functions as a resistance load (for example, 80Ω) for discharging the output smoothing capacitor C3 when the semiconductor device 100 is shut down from an operation state by enable control. In other words, when the semiconductor device 100 is shut down, and thus when both the upper transistor 101 and the lower transistor 102 are turned off, the transistor 115 is preferably turned on. The output voltage VOUT may be discharged to 10% of a target value.

The comparator 116 monitors a voltage across the upper transistor 101 (=VIN−VSW) for each cycle of a switching period, and generates an upper overcurrent detection signal HOCP. When a current flowing through the upper transistor 101 reaches an overcurrent detection value IOCPH while the upper transistor 101 is on, the upper overcurrent detection signal HOCP is switched high. Here, the control logic 105 turns off the upper transistor 101 and turns on the lower transistor 102.

The comparator 117 monitors a voltage across the lower transistor 102 (=VSW) for each cycle of the switching period, and generates a lower overcurrent detection signal LOCP. When a current flowing through the lower transistor 102 reaches an overcurrent detection value IOCPL while the lower transistor 102 is on, the lower overcurrent detection signal LOCP is switched high. Here, even when a feedback voltage FB drops below the internal reference voltage VREF, the control logic 105 turns off the upper transistor 101 to keep a state where the lower transistor 102 is on. Thereafter, the current flowing through the lower transistor 102 drops below an upper limit value, the upper transistor 101 can be turned on.

The comparator 118 monitors a voltage across the lower transistor 102 (=VSW) for each cycle of the switching period, and generates a zero cross/sink (reverse) overcurrent detection signal ZX/ROCP. For example, in the light load mode, the control logic 105 detects zero cross timing for the current flowing through the lower transistor 102 when the lower transistor 102 is on, and turns off the lower transistor 102. In the fixed PWM mode, when the lower transistor 102 is on, the control logic 105 detects that a sink current (reverse current) flowing from the SW terminal toward the lower transistor 102 has reached an upper limit value, and the control logic 105 turns off the lower transistor 102 and turns on the upper transistor 101.

The low input voltage malfunction prevention circuit 119 monitors the input voltage VIN and the internal power supply voltage VCC, and applies UVLO (under voltage lock out) protection. For example, when the input voltage VIN is equal to or less than 1.85 V or the internal power supply voltage VCC is equal to or less than 2.5 V, the semiconductor device 100 is shut down. On the other hand, when the input voltage VIN is equal to or greater than 2.4 V and the internal power supply voltage VCC is equal to or greater than 2.8 V, the semiconductor device 100 is started up.

The temperature protection circuit 120 monitors the junction temperature Tj of the semiconductor device 100, and applies temperature protection. For example, when the junction temperature Tj is equal to or greater than 175° C., the semiconductor device 100 is shut down. Thereafter, when the junction temperature Tj is equal to or less than 150° C. (hysteresis of 25° C.), the semiconductor device 100 is automatically restarted.

The low voltage protection circuit 121 monitors the feedback voltage VFB, and applies low voltage protection. For example, when after the semiconductor device 100 is started up, the feedback voltage VFB is equal to or less than 80% of the internal reference voltage VREF, the semiconductor device 100 is shut down. When a time period of 117 ms elapses after the shutting down, the semiconductor device 100 is automatically restarted.

The overvoltage protection circuit 122 monitors the feedback voltage VFB, and applies overvoltage protection. For example, when the feedback voltage VFB is equal to or greater than 116% of the internal reference voltage VREF, the lower transistor 102 is turned on, and thus a rise in the output voltage VOUT is suppressed. Thereafter, when the feedback voltage VFB is equal to or less than 105% of the internal reference voltage VREF, the state is returned to a normal operation state.

The power good circuit 123 monitors the feedback voltage VFB, and performs on/off control on the transistor 124 (hence, output control on a power good signal PGD). For example, when the output voltage VOUT reaches a target value of 92.5% to 105%, and its state continues over a time period of 0.9 ms, the transistor 124 is turned off. On the other hand, when the output voltage VOUT is equal to or greater than 116% or equal to or less than 80%, the transistor 124 is turned on.

The drain of the transistor 124 is connected to the PGD terminal. The source of the transistor 124 is connected to the ground end (=AGND terminal). As described above, the transistor 124 is turned on and off by the power good circuit 123. When the transistor 124 is off, the PGD terminal is in a high impedance state. On the other hand, when the transistor 124 is on, the PGD terminal is pulled down to the ground end. The power good function as described above is included, and thus it is possible to perform sequence control on the overall system.

The mode selector 125 sets a switching frequency FREQ and an operation mode MODE according to the state of the MODE terminal. When the light load mode is selected as the operation mode, in a heavy load state, the switching operation is performed by PWM mode control, and in a light load state, the switching operation is performed by LLM (light load mode) mode control. On the other hand, when the fixed PWM mode is selected as the operation mode, the switching operation is forcibly performed by the PWM mode control regardless of the weight of a load. Since the efficiency of a light load region is improved in the light load mode, this function is suitable for a device which needs to reduce standby power consumption.

### <Oscillation Prevention Circuit>

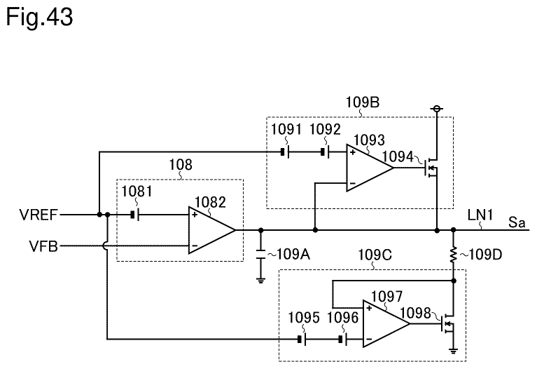

An oscillation prevention circuit includes the signal line LN1 described above, the capacitor 109A, the upper clamp circuit 109C and the resistor 109D. The oscillation prevention circuit forms a switching control circuit which controls the upper transistor 101 and the lower transistor 102 together with the error amplifier 108, the main comparator 112, the on-time setting circuit 113 and the control logic 105. FIG. 43 is a diagram showing a configuration example of the error amplifier 108, the lower clamp circuit 109B and the upper clamp circuit 109C.

The error amplifier 108 includes a direct-current voltage source 1081 and an error amplifier 1082. The direct-current voltage source 1081 is connected to the non-inverting input terminal (+) of the error amplifier 1082 and supplies a voltage obtained by adding a first offset voltage to the internal reference voltage VREF to the non-inverting input terminal (+) of the error amplifier 1082.

The lower clamp circuit 109B includes a direct-current voltage source 1091, a direct-current voltage source 1092, a differential amplifier 1093 and an NMOS field effect transistor 1094 which functions as a switch. The direct-current voltage source 1091 supplies a voltage obtained by adding a second offset voltage to the internal reference voltage VREF to the direct-current voltage source 1092. The direct-current voltage source 1092 supplies, to the non-inverting input terminal (+) of the differential amplifier 1093, a voltage obtained by adding a voltage corresponding to the first predetermined value described above to a total voltage of the internal reference voltage VREF and the second offset voltage. The inverting input terminal (−) of the differential amplifier 1093 is connected to the signal line LN1.

When the error signal Sa is lowered to the first predetermined value, the differential amplifier 1093 turns on the NMOS field effect transistor 1094. When the NMOS field effect transistor 1094 is turned on, the capacitor 109A is charged, and thus a decrease in the error signal Sa is suppressed. Hence, the lower clamp circuit 109B clamps the error signal Sa such that the error signal Sa is prevented from dropping below the first predetermined value.

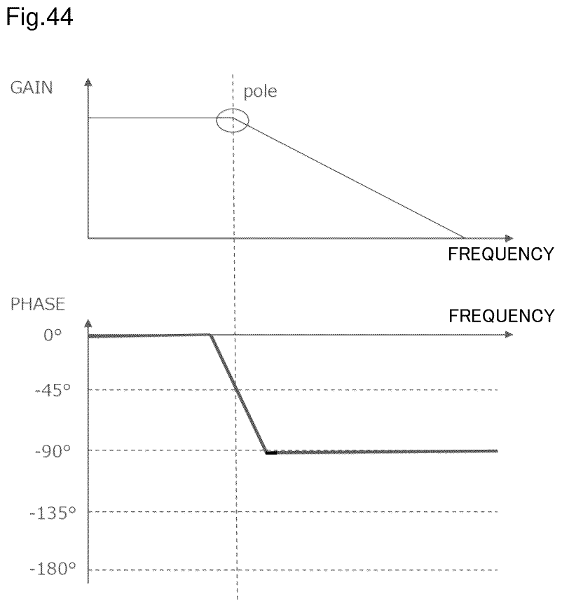

Since the output impedance of the differential amplifier 1093 is high, and the output impedance of the NMOS field effect transistor 1094 is low, the lower clamp circuit 109B includes only one pole (see FIG. 44). Consequently, in the lower clamp circuit 109B, the phase is delayed only by 90° (see FIG. 44). Hence, the lower clamp circuit 109B does not oscillate.

The upper clamp circuit 109C includes a direct-current voltage source 1095, a direct-current voltage source 1096, a differential amplifier 1097 and an NMOS field effect transistor 1098 which functions as a switch. The direct-current voltage source 1095 supplies a voltage obtained by adding a third offset voltage to the internal reference voltage VREF to the direct-current voltage source 1096. The direct-current voltage source 1096 supplies, to the inverting input terminal (−) of the differential amplifier 1097, a voltage obtained by adding a voltage corresponding to the second predetermined value described above to a total voltage of the internal reference voltage VREF and the third offset voltage. The non-inverting input terminal (+) of the differential amplifier 1097 is connected to the first end of the resistor 109D. The second end of the resistor 109D is connected to the signal line LN1.

When the error signal Sa is increased to the second predetermined value, the differential amplifier 1097 turns on the NMOS field effect transistor 1098. When the NMOS field effect transistor 1098 is turned on, the capacitor 109A is discharged, and thus an increase in the error signal Sa is suppressed. Hence, the upper clamp circuit 109C clamps the error signal Sa such that the error signal Sa is prevented from exceeding the second predetermined value.

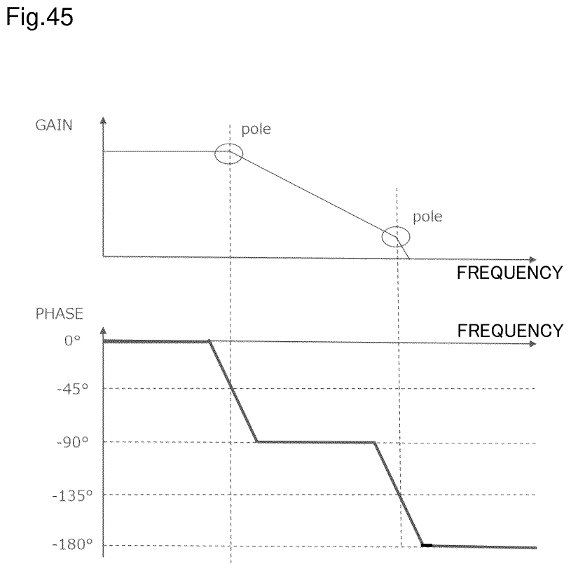

Since the output impedances of both the differential amplifier 1097 and the NMOS field effect transistor 1094 are high, the upper clamp circuit 109C includes two poles (see FIG. 45). Consequently, in the upper clamp circuit 109C, the phase is delayed by 180° (see FIG. 45). Hence, the upper clamp circuit 109C oscillates.

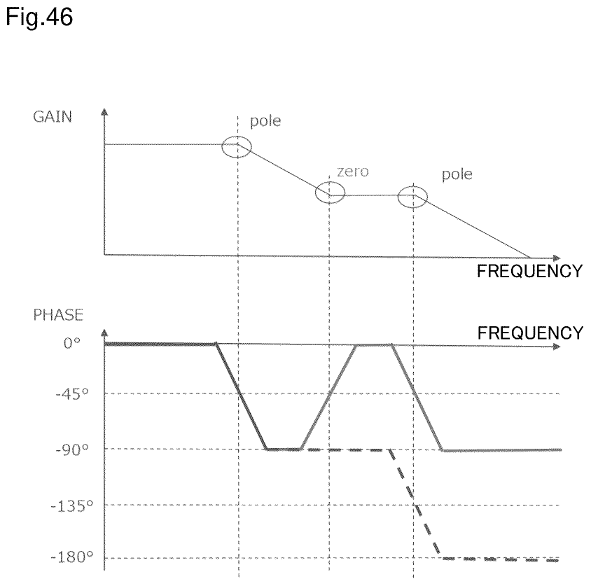

However, the upper clamp circuit 109C, the capacitor 109A and the resistor 109D include two poles and one zero point (see FIG. 46). Since the zero point returns the phase by 90°, in the upper clamp circuit 109C, the capacitor 109A and the resistor 109D, the phase is delayed only by 90°. Hence, the oscillation prevention circuit in the present embodiment can prevent the oscillation of the upper clamp circuit 109C. In other words, the zero point is generated by the capacitor 109A and the resistor 109D, and thus the oscillation of the upper clamp circuit 109C is prevented.

The capacitor 109A is a phase compensation circuit for preventing the oscillation of the error amplifier 108, and is also used for preventing the oscillation of the upper clamp circuit 109C. In other words, the capacitor 109A includes the two functions. In this way, an increase in the number of components is suppressed.

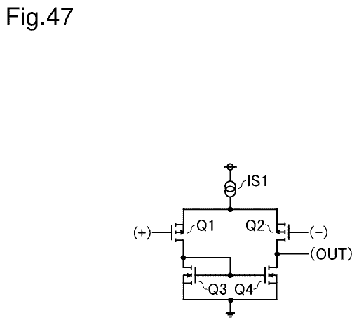

FIG. 47 is a diagram showing a configuration example of the differential amplifier 1097. The differential amplifier 1097 in the configuration example shown in FIG. 47 includes a current source IS1, P-channel MOS field effect transistors Q1 and Q2 which are an input differential pair and N-channel MOS field effect transistors Q3 and Q4 which form a current mirror circuit.

The first end of the current source IS1 is connected to a power supply voltage application end. The second end of the current source IS1 is connected to the sources of the P-channel MOS field effect transistors Q1 and Q2. The drains of the P-channel MOS field effect transistors Q1 and Q2 are connected to the drains and gates of the N-channel MOS field effect transistors Q3 and Q4. The sources of the N-channel MOS field effect transistors Q3 and Q4 are connected to the ground potential.

### Others

In addition to the embodiments described above, the configuration of the invention can be variously changed without departing from the spirit of the invention. The embodiments described above should be considered to be illustrative in all respects and not restrictive, and it should be understood that the technical scope of the present invention is indicated not by the description of the embodiments but by the scope of claims, and meaning equivalent to the scope of claims and all changes belonging to the scope are included therein.

Although in the present embodiment, the oscillation prevention circuit is provided in a stage subsequent to the error amplifier, the location of the installation of the oscillation prevention circuit is not limited to the subsequent stage. The oscillation prevention circuit may be incorporated in a device other than a switching power supply device.

### Additional Description

The oscillation prevention circuit described above includes: a signal line (LN1); a first circuit (109C); a capacitor (109A) connected to the signal line; and a resistor (109D) provided between the signal line and the first circuit, the first circuit includes two poles and the first circuit, the capacitor and the resistor include two poles and one zero point (first configuration).

The oscillation prevention circuit of the first configuration can prevent the oscillation of the first circuit including the two poles.

In the oscillation prevention circuit of the first configuration, the first circuit may be a clamp circuit configured to clamp a voltage applied to the signal line such that the voltage applied to the signal line is prevented from exceeding a predetermined value (second configuration).

The oscillation prevention circuit of the second configuration can prevent the voltage applied to the signal line from exceeding the predetermined value.

In the oscillation prevention circuit of the second configuration, the clamp circuit may include a differential amplifier (1097) configured to output a voltage corresponding to a difference between the voltage applied to the signal line and a voltage of the predetermined value and a switch (1098) configured to be controlled by the voltage output from the differential amplifier, and when the switch is on, the capacitor may be discharged (third configuration).

The oscillation prevention circuit of the third configuration uses a simple circuit configuration, and thereby can prevent the voltage applied to the signal line from exceeding the predetermined value.

In the oscillation prevention circuit of the third configuration, the switch may be an N-channel MOS field effect transistor (fourth configuration).

The oscillation prevention circuit of the fourth configuration can reduce the size of the switch.

In the oscillation prevention circuit of any one of the first to fourth configurations, the signal line may be connected to an output end of a second circuit (fifth configuration).

The oscillation prevention circuit of the fifth configuration can be provided in a stage subsequent to the second circuit.

In the oscillation prevention circuit of the fifth configuration, the second circuit may be an error amplifier (108) (sixth configuration).

The oscillation prevention circuit of the sixth configuration can use the capacitor to prevent the oscillation of the error amplifier.

The switching control circuit described above includes: the oscillation prevention circuit of the sixth configuration; the error amplifier; and a control unit (112, 113, 105) configured to control a switching element based on an output voltage of the error amplifier (seventh configuration).

The switching control circuit of the seventh configuration can prevent the oscillation of the first circuit including the two poles.

The switching power supply device described above includes: the switching control circuit of the seventh configuration; and the switching element (101, 102) (eighth configuration).

The switching power supply device of the eighth configuration can prevent the oscillation of the first circuit including the two poles.

### INDUSTRIAL APPLICABILITY

The present disclosure can be utilized, for example, for a semiconductor device which has a DC/DC converter function.

### LIST OF REFERENCE SYMBOLS

1 semiconductor device
2 gate drive circuit
3 control logic unit
4 switch
21 high-side pre-driver
22 low-side pre-driver
23 high-side gate voltage monitoring unit
23A resistor
23B, 23C switch
23D, 23E inverter
211 first high-side drive unit
211A, 211B inverter
212 second high-side drive unit
221 first low-side drive unit
221A, 221B inverter
221C inverter
221D AND circuit
222 second low-side drive unit
2111 first high-side gate signal generation unit
2112 second high-side gate signal generation unit
2211 first low-side gate signal generation unit
2212 second low-side gate signal generation unit
Cbst boot capacitor
Cout output capacitor
HM high-side transistor
HNM1 first high-side NMOS transistor
HNM2 second high-side NMOS transistor
HPM1 first high-side PMOS transistor
HPM2 second high-side PMOS transistor
L inductor
LM low-side transistor
LNM1 first low-side NMOS transistor
LNM2 second low-side NMOS transistor
LPM1 first low-side PMOS transistor
LPM2 second low-side PMOS transistor

1. A gate drive circuit configured to drive a half bridge in which a high-side transistor to be driven and a low-side transistor to be driven are connected in series between a power supply voltage and a ground potential, the gate drive circuit comprising:
a high-side pre-driver configured to drive a gate of the high-side transistor to be driven; and
a low-side pre-driver configured to drive a gate of the low-side transistor to be driven,
wherein the high-side pre-driver includes a first high-side transistor and a second high-side transistor,
the low-side pre-driver includes a third high-side transistor and a fourth high-side transistor and
a delay is provided in at least one of
a time period between a first gate signal configured to turn on the first high-side transistor and a second gate signal configured to turn on the second high-side transistor and
a time period between a third gate signal configured to turn on the third high-side transistor and a fourth gate signal configured to turn on the fourth high-side transistor.

2. The gate drive circuit according to claim 1,
wherein the high-side pre-driver includes a high-side drive unit configured to generate the first gate signal and the second gate signal based on a high-side control input signal.

3. The gate drive circuit according to claim 2,
wherein the high-side drive unit includes
a first high-side gate signal generation unit configured to include a plurality of first inverters to generate the first gate signal and
a second high-side gate signal generation unit configured to include a plurality of second inverters to generate the second gate signal, and
at least one of the second inverters in the second high-side gate signal generation unit are smaller in a size of a transistor than at least one of the first inverters in the first high-side gate signal generation unit.

4. The gate drive circuit according to claim 3,
wherein the second inverter in a first stage included in the second high-side gate signal generation unit is smaller in the size of the transistor than the first inverter in a first stage included in the first high-side gate signal generation unit.

5. The gate drive circuit according to claim 1,
wherein the low-side pre-driver includes a low-side drive unit configured to generate the third gate signal and the fourth gate signal based on a low-side control input signal.

6. The gate drive circuit according to claim 5,
wherein the low-side drive unit includes
a first low-side gate signal generation unit configured to include a plurality of third inverters to generate the third gate signal and
a second low-side gate signal generation unit configured to include a plurality of fourth inverters to generate the fourth gate signal, and
at least one of the fourth inverters in the second low-side gate signal generation unit are smaller in a size of a transistor than at least one of the third inverters in the first low-side gate signal generation unit.

7. The gate drive circuit according to claim 6,
wherein the fourth inverter in a first stage included in the second low-side gate signal generation unit is smaller in the size of the transistor than the third inverter in a first stage included in the first low-side gate signal generation unit.

8. The gate drive circuit according to claim 1, further comprising:
a monitoring unit configured to monitor
whether a gate voltage of the high-side transistor to be driven is low and
whether a voltage at a node where the high-side transistor to be driven and the low-side transistor to be driven are connected is low,
wherein the fourth gate signal is generated based on a monitor signal output from the monitoring unit.

9. The gate drive circuit according to claim 8,
wherein the monitoring unit includes
a resistor configured to include a first end connected to the gate of the transistor to be driven and
an inverter stage configured to include an input end connected to a second end of the resistor.

10. A power good circuit comprising:
a first output transistor configured to include
a first end connected to a power good terminal and
a second end connected to an application end of a ground potential;
a resistor configured to apply a voltage based on a first power supply voltage to a control end of the first output transistor;
a first inverter stage configured to use a second power supply voltage as a power supply voltage to input a control input signal; and
a second output transistor configured to include
a control end connected to an output end of the first inverter stage,
a first end connected to the power good end and
a second end connected to the application end of the ground potential,
wherein the power good terminal is capable of being pulled up to the second power supply voltage.

11. The power good circuit according to claim 10,
wherein the resistor is a voltage dividing resistor connected in series between an application end of the first power supply voltage and the application end of the ground potential, and
a connection node of the voltage dividing resistor is connected to the control end of the first output transistor.

12. The power good circuit according to claim 11,
wherein the first output transistor and the second output transistor are the same transistor, and
the power good circuit further includes
a first diode configured to block a path extending from the connection node via the voltage dividing resistor to the application end of the first power supply voltage and
a second diode configured to block a path extending from the connection node via the first inverter stage to an application end of the second power supply voltage.

13. The power good circuit according to claim 10,
wherein the resistor is a first pull-up resistor connected between an application end of the first power supply voltage and the control end of the first output transistor.

14. The power good circuit according to claim 13,
wherein the first output transistor and the second output transistor are separate transistors.

15. The power good circuit according to claim 14, further comprising:
a second pull-up resistor connected between a control end of the second output transistor and an application end of the second power supply voltage.

16. The power good circuit according to claim 14, further comprising:
a level-shift circuit configured to level shift the control input signal from the second power supply voltage to the first power supply voltage; and
a second inverter stage provided between an output end of the level-shift circuit and the control end of the first output transistor to use the first power supply voltage as the power supply voltage.

17. The power good circuit according to claim 14, further comprising:
a control transistor configured to include
a first end connected to the control end of the first output transistor,
a second end connected to the application end of the ground potential and
a control end connected to the application end of the second power supply voltage.

18. A semiconductor device comprising:
the power good circuit according to claim 10;
a pre-regulator configured to input an enable signal to generate the first power supply voltage;
a reference voltage generation unit configured to generate a reference voltage based on the first power supply voltage; and
a regulator configured to be started up based on the reference voltage to generate the second power supply voltage.

19. An overcurrent detection circuit
configured such that a first switch and a second switch are connected in series, and the second switch is provided on a lower potential side than the first switch, and
configured to detect an overcurrent flowing through the second switch in a circuit in which an inductor is connected to a connection node of the first switch and the second switch, the overcurrent detection circuit comprising:
a first current generation circuit configured to generate a first current corresponding to a current flowing through the second switch;
a second current generation circuit configured to generate a second current that
is greater than zero with timing at which the second switch is switched from off to on and
varies in synchronization with switching of the first switch and the second switch; and
a comparator configured to compare a voltage corresponding to the first current and the second current with a threshold value.

20. The overcurrent detection circuit according to claim 19,
wherein the second current generation circuit includes
a third switch configured to be on when the first switch is on and to be off when the first switch is off or
a fourth switch configured to be off when the first switch is on and to be on when the first switch is off.

21. The overcurrent detection circuit according to claim 19,
wherein the second current generation circuit includes a circuit configured with a resistor and a capacitor.

22. The overcurrent detection circuit according to claim 19,
wherein the second current is increased with time when the second switch is off, and is decreased with time when the second switch is on.

23. The overcurrent detection circuit according to claim 19,
wherein the second current generation circuit includes
a third switch configured to be on when the first switch is on and to be off when the first switch is off and
a fourth switch configured to be off when the first switch is on and to be on when the first switch is off.

24. The overcurrent detection circuit according to claim 19,
wherein the second current generation circuit is configured to hold information of the first current immediately before the second switch is turned off.

25. The overcurrent detection circuit according to claim 24,
wherein the second current has a value corresponding to the information when the second switch is off.

26. The overcurrent detection circuit according to claim 19,
wherein the first current generation circuit is configured to cancel an offset in an input differential pair of transistors in the first current generation circuit.

27. A switching control circuit comprising:
the overcurrent detection circuit according to claim 19; and
a control unit configured to control the first switch and the second switch.

28. A switching power supply device comprising:
the switching control circuit according to claim 27; and
the first switch and the second switch.

29. An oscillation prevention circuit comprising:
a signal line;
a first circuit;
a capacitor connected to the signal line; and
a resistor provided between the signal line and the first circuit,
wherein the first circuit includes two poles, and
the first circuit, the capacitor and the resistor include two poles and one zero point.

30. The oscillation prevention circuit according to claim 29,
wherein the first circuit is a clamp circuit configured to clamp a voltage applied to the signal line such that the voltage applied to the signal line is prevented from exceeding a predetermined value.

31. The oscillation prevention circuit according to claim 30,
wherein the clamp circuit includes
a differential amplifier configured to output a voltage corresponding to a difference between the voltage applied to the signal line and a voltage of the predetermined value and
a switch configured to be controlled by the voltage output from the differential amplifier, and
when the switch is on, the capacitor is discharged.

32. The oscillation prevention circuit according to claim 31,
wherein the switch is an N-channel MOS field effect transistor.

33. The oscillation prevention circuit according to claim 29,
wherein the signal line is connected to an output end of a second circuit.

34. The oscillation prevention circuit according to claim 33,
wherein the second circuit is an error amplifier.

35. A switching control circuit comprising
the oscillation prevention circuit according to claim 34;
the error amplifier; and
a control unit configured to control a switching element based on an output voltage of the error amplifier.

36. A switching power supply device comprising:
the switching control circuit according to claim 35; and
the switching element.
